(19) United States
(12) Patent Application Publication
(10) Pub. No.: US 2011/0125337 A1
(43) Pub. Date: May 26, 2011

(54) Household appliance adapted to work with time of use electricity rates

(76) Inventors: Vyacheslav Zavadsky, Ottawa (CA); Mykola Sherstyuk, Ottawa (CA)

(21) Appl. No.: 13/007,617

(22) Filed: Jan. 15, 2011

Related U.S. Application Data
(60) Provisional application No. 61/378,373, filed on Aug. 30, 2010.
(60) Provisional application No. 61/414,404, filed on Nov. 16, 2010.

(51) Int. Cl. G06F 1/28; G01R 21/133

(52) U.S. Cl. 700/291; 705/412

(57) ABSTRACT

An electrical appliance with reduced operating costs is described. The appliance incorporates electrical storage which is charged from the grid during periods of low electricity pricing and discharged during periods of high pricing. Storage cycles are engineered to minimize energy losses and reduce appliance operating costs. Energy losses are minimized by only charging the storage to a portion of full capacity and only discharging to a specified value. In one embodiment the storage consists of a battery and a capacitor. The capacitor provides additional current during high demand intervals. In another embodiment the external supply provides this. Storage lifetime is improved by maintenance cycles. The appliance computes the cost of an operation for multiple scenarios and either selects the optimal scenario or allows user selection. The appliance can communicate with a home energy server to manage multiple appliances and communicate with ancillary grid services.

### CLAIM OF PRIORITY

This application claims priority under 35 USC Section 119(a) from U.S. Provisional Application No. 61/378,373, filed Aug. 30, 2010. This application further claims priority under 35 USC Section 119(a) from U.S. Provisional Application No. 61/414,404, filed Nov. 16, 2010. Those applications are incorporated herewith by reference.

### FEDERALLY SPONSORED RESEARCH OR DEVELOPMENT

None.

### BACKGROUND OF THE INVENTION

Variable, daily time-of-use (TOU) consumer electricity billing rates are becoming increasingly common in the industrialized and developing world. In TOU billing the utility supplied electrical power is priced lower during off-peak demand times (typically weekends and nights) and higher during peak demand times.

For example, in Tokyo, the night rate is 6.1 Y/kwh, while the daytime rate is 15 Y/kwh. In some jurisdiction, the difference is as much as 6 times. In some jurisdictions, such as Italy, consumers do not have fixed TOU rates, but paying TOU rates based on “spot prices” of the electricity that can vary even more significantly. In some jurisdiction, time of use rates regime is further complicated by usage of tiered rates (when electricity rates depend on the amount of electricity consumed).

Although TOU rates are designed to motivate consumers to reduce their electrical consumption at peak demand periods the effectiveness of TOU rates is so far limited for a number of reasons. Some consumers are unwilling to adjust their consumption patterns. Some electrical demand cannot be shifted to off peak periods and there are limited technological solutions that allows consumers to benefit from TOU savings without adversely affecting lifestyle.

Existing art in the field includes U.S. Pat. No. 6,885,115 by Hatori et al. describing a laptop computer in which peak demand is reduced by charging the laptop battery during off peak demand periods and then powering the laptop from the battery during a portion of the peak demand period. External power is used during off peak times. The laptop switches back to external power when the state of charge of the battery becomes too low to power the laptop.

U.S. Pat. No. 7,206,944 by Odaohara et al. also discloses a laptop computer where a battery is used to reduce peak demand. The computer is switched from the external power supply to the battery at the start of a peak demand period. The computer has a plurality of subsystem each capable of being independently supplied from either the external supply or the battery. Some subsystems are switched back to external power when the state of charge of the battery becomes too low to power the entire computer.

US Patent application 2009/0153102 by Guatto et al. discloses an electrical utility storage facility based on ZEBRA Sodium-Nickel-Chloride batteries. Peak demand is reduced by charging the batteries during off peak times and distributing the stored power to the grid during peak periods.

US Patent application 2003/0061828 by Blevins discloses a central air-conditioner with battery storage to reduce peak loads by running the air conditioner from the battery during peak demand periods. The battery is recharged during off peak demand periods.

U.S. Pat. No. 7,266,962 to Montuoro et al. discloses a battery supplemented refrigerator. Peak demand is reduced by powering the refrigerator from the battery pack through an inverter during a portion of the peak demand period. The refrigerator is powered from an AC power source during a portion of the reduced demand period. The refrigerator shifts from the AC source to the battery pack in the event of an AC power failure. Non-essential sub systems (e.g. an ice maker) are turned off when running off the battery pack when the state of charge of the battery pack drops below a specific level.

U.S. application Ser. No. 12/485,167 by Sundaresh et al teaches the concept of monitoring power consumption by household appliances using a single current sensor located at an electrical panel or electricity meter. The specific appliance responsible for a change in demand level is recognized by a consumption pattern. There is no disclosure of TOU rates or cost calculations. Recently, Google power meter implemented a similar concept and enhanced it by cost monitoring using TOU rates.

In 2009, General Electric announced a series of “energy management aware energy star consumer appliances”. The promotional video titled “New Suite of GE Appliances” at http://www.geappliances.com/videos-media/ and viewed Nov. 25, 2010 describes a system for remote and centralized monitoring of the appliances and switching some or all to energy saving mode during peak demand times. For example, a water heater might reduce its temperature set point, or a dishwasher delays dishwashing. Notification of the affected consumers by using a smartphone, and optional consumer override is described. An electrical clothes dryer generally designed according to this concept is described in U.S. application Ser. No. 12/559,684 by M. Finch et al.

U.S. Pat. No. 7,110,832 to Ghent teaches a demand shifting capable electrical appliance. Demand shifting is achieved by postponing an operation till it can be performed during off-peak time. This approach inconveniences consumers without enabling them to make informed decisions about demand shifting.

U.S. application Ser. No. 12/559,568 by Cooper discloses a household appliance capable of displaying current operational costs and which allows the consumer to receive information about future operating costs depending on operational parameters of the appliance. The cost computation depends only on current electricity cost, not overall TOU regime. Further, the electricity use is estimated based on operational parameter such as temperature, number of times door was open, ice making use, etc. Such an estimate is inaccurate and will be increasingly inaccurate as the appliance ages. Cooper enables the consumer to approximately optimize the appliance parameters to reduce overall energy consumption, but does not enable demand shifting or takes into account TOU rates.

A “smart” power bar is described in the article “Pulling the plug on electricity leaks” by Michael Woods, May 2005, Pittsburgh post gazette, downloaded from http://www.post-gazette.com/pg/05128/500530.stm in November 2010. These devices cut-off standby consumption of any appliances connected to them at either predetermined times, or in response of power demand falling below a predetermined threshold.

US application 2007/0276547 by Miller discloses an optimized energy management system for an entire home or other large facility; the system integrates local electrical generation and storage with utility supplied electricity. Demand shifting is enabled by using stored, locally generated power. Alternately, power may be sold to the grid during high TOU rates and replenished during low TOU rates. The storage is a separate appliance that is expensive and must be connected to the household grid by a professional electrician. Storage is considered to have a fixed energy efficiency (see eq. 10 in Miller) and to have a fixed cost of executing a storage cycle (see eq. 11 in Miller). There is no attempt to improve energy efficiency or reduce cycling costs through smarter operation of the storage. The system provides no interaction with the consumer to select an operating cycle. Further, the system utilizes storage in full charge/full discharge mode (follows from the model in eq. 10 and eq. 11 and follow up discussion on “buy/sell” storage).

### To Conclude,

the known art teaches peak demand reduction by storing power during periods of low demand and using the stored power during times of peak demand. The known art further teaches peak demand reduction by means of delaying electrical usage, where the process is typically controlled by an electrical utility company.

A deficiency of the known art is that a reduction in peak demand only provides a benefit to the electrical utility in the form of reduction in the utility's required peak generation and distribution capacities. The known art does not teach system energy efficiency or reduction in the electrical consumer's operating costs.

For instance, the capacity of many battery types is significantly diminished at high discharge currents. High currents are characteristic of many common household appliances with inductive loads such as air conditioners, refrigerators or forced air furnaces. Thus, in the prior art, a significant portion of the energy that was stored during off peak times may not be delivered to the load if the storage is discharged at too high a current. Additionally, for certain batteries, charge storage becomes increasingly inefficient as their State Of Charge (SOC) increases. Thus, at a sufficiently high SOC, a large portion of the charging energy is dissipated in the battery and never actually stored. Similarly all batteries self discharge over time. Thus, if the battery is not discharged in a timely manner some fraction of the charging energy may have dissipated by the self discharge mechanism. The costs of this lost energy may negate any savings to the consumer from using off peak energy.

Thus, known art only teaches a reduction in peak power demand and consequent reduced strain on the electrical utility's generation and distribution systems. It does not teach a reduction in the electrical costs for the electrical consumer, or reduction of combined utility and storage costs.

The known art also does not consider the useful lifetime of the storage system and concomitant costs. For instance, it is known that the useful number of charge/discharge cycles of certain battery types is significantly reduced by high discharge currents or discharging to very low SOC. In the art (see, for example, Montuoro) the storage battery operates by charging to its maximum SOC during off-peak hours and discharging during peak hours. Such battery operation will lead to reduced battery lifetime (discharge with low SOC and high current) and low overall efficiency of the system (charge to high SOC). Too short a storage lifetime may eliminate any cost savings from using off peak energy.

Another deficiency of the known art is that it is limited to only two demand periods while many jurisdictions use multiple demand periods.

Another deficiency of the known art is that it does not provide the consumer enough information to make informed energy use decisions. A consumer might be willing to delay use of an energy intensive appliance cycle to an off-peak time if aware of the costs of the different options.

Therefore, there is a need in the art to and provide the electrical consumer an effective way of realizing the potential cost savings from TOU billing rates.

### BRIEF SUMMARY OF THE INVENTION

It is an objective of this invention to provide an economically beneficial demand shifting method for the consumer that takes into the account all important consumer costs, including energy, storage deterioration, capital, and inconvenience cost.

It is an objective of this invention to provide the consumer with real time feedback on the cost of various options to operate an appliance, including demand shifting options, where such costs are computed using a TOU rate schedule and demand shifting options can be either delaying operations, or using storage, or both.

It is an objective of this invention to use electrical storage for a economically beneficial demand shifting.

It is an objective of this invention to achieve some or all of thevbjectives above by providing a household electrical appliance or system of household electrical appliances and a computing device.

An aspect of the invention is an electrical appliance supplied with power from an electrical utility grid and incorporating electrical storage to enable electrical power demand shifting. The utility grid power is billed at variable rates according to the time of use of the power. An object of the invention is to provide a demand shifting scheme which achieves energy efficiency and operating cost reduction for the consumer rather than a reduction in peak electrical demand for the electrical utility as in the prior art.

It is an aspect of this invention that the cost computations and/or storage to practice economically beneficial demand shifting are either embedded into an utility appliance, or in a separate easy to deploy appliance that is inserted in the power supply path of an appliance.

In one embodiment, the appliance performs additional useful functions besides storage based demand shifting such as those performed by any one of a number of common appliances, such as for example, but not limited to, a refrigerator, a freezer, a water heater, blower motor or television. Another embodiment of the invention is solely an electrical storage and demand shifting appliance through which other existing appliances are powered.

The electrical storage uses batteries, capacitors, super capacitors or other electrical storage devices. The storage is charged from the electrical grid during periods of low electricity prices rates and discharged during periods of high electricity prices. In accordance with another object of the invention, the storage charge and discharge operations are engineered to maximize energy efficiency and storage lifetime and hence reduce the total appliance operating costs.

It is an aspect of the present invention to compute the operating cost of a utility appliance, (e.g. a refrigerator, dryer, TV, computer) over a given period of time, such as a day, a week, a month, or to complete a single operation (e.g. to dry a load of clothes or to wash a load of dishes), taking into account time of use rates. Operating costs include at least the cost of the electricity, but may further include costs of other consumables (e.g. water, water filter, detergent), storage deterioration costs, appliance deterioration costs, etc.

The appliance contains a microcontroller unit that is aware of the amount of the electrical current consumed by the appliance. This is achieved either by using at least one current sensor, or by computing the current from operational parameters of the appliance (e.g. current use information is computed by a motor controller).

For a given operation, the appliance computes costs for a plurality of use scenarios. Use scenario variables include the amount of storage usage and timing of the performance of the operation. In an embodiment, the costs are computed both for a “status quo” use scenario and for appliance use with demand shifting enabled by storage. The computed costs are presented to the customer to report on actual or potential savings achieved by using the storage. In an embodiment, just the difference between costs for two use scenarios is computed. In an embodiment, cost computation is done for anticipated use scenarios and takes into account the anticipated time of use rate(s).

In one embodiment, for each of a plurality of use scenarios with different demand shifting and cycle optioned (e.g. delayed time of use, pot scrubbing, delicate wash, hot, warm or cold water temperature) the user can see the costs (or cost difference) to perform this scenario. This enables the user to make an informed choice of an economically beneficial use scenario that takes into the account potential expenses or savings due to TOU rates.

In another embodiment, computation of operation costs for a plurality of use scenarios is done automatically to select the optimum cycle. The user requirements (or preferences) can be either incorporated into costs, or be part of an optimization process as conditions.

In another embodiment, a combined process is used: for each of the plurality of use scenario; the most cost effective use scenario is computed, potentially using the storage, and then the user selects from a plurality of already pre-optimized use scenarios. For example, user will select a finish time for dryer cycle. A use scenario that dries clothes before the selected time will be found using a cost optimization process. This cost will be displayed to the user. User will iterate over a plurality of finish times and will make an informed decision with respect to cost/convenience. Appliance may suggest the cheapest use scenario, or balanced use scenario, or quickest use scenario within cost limits.

In one embodiment, the entire process of cost computation, optimization, and display actually happens on the appliance. In another embodiment, the appliance communicates with another computing device, such as PC, Smartphone, home energy management server, etc to perform some of these functions.

An aspect of this invention is a household utility appliance containing electricity storage to enable demand shifting by charging the storage during period of low TOU rates and discharging the storage while operating appliance at high TOU rates. To achieve low consumer costs, the charge and/or discharge operation is performed in a manner to reduce the negative effects of storage operation (such as energy losses or storage lifetime reduction) and achieve low consumer costs.

In one embodiment, the charging time to charge a battery to a predetermined SOC t is maximized to reduce battery lifetime deterioration. For example, a lead-acid batteries is beneficially charged to 80% SOC and a Li-ion batter to a 40% SOC. In another embodiment, the time the storage is in a charged state but idle state is minimized. This is to reduce energy loss by self discharge (for battery chemistries with high self discharge rate, (e.g. Zebra or super capacitor) or to reduce battery deterioration.

In another embodiment, the battery is charged (discharged) to a first threshold, and then to a second threshold different from the first threshold. This has the beneficial effect of reducing the memory effect for some chemistries (e.g. NiCd, NiMh) or to reduce deterioration of the battery for other chemistries (e.g. Lead acid). In other embodiments pulse charging or discharging techniques may be used, different charge or discharge currents during different cycles may be used, or the battery may be placed in a thermally controllable compartment. All the above techniques reduce battery deterioration and losses for different chemistries.

In another embodiment the appliance is fully or partially powered from the external supply during periods of high but brief demand to limit the storage discharge current This reduces battery damage during periods of high demand (e.g., a motor start-up) where the cost of short term use of external power at peak prices is smaller than the cost associated with damage to the battery.

In an embodiment, the appliance further comprises a second energy storage, wherein the first storage discharges at a small current into a secondary storage and secondary storage is used to power the appliance at high current. For example, the first storage might be a lead acid battery which would deteriorate and suffer from capacity reduction at high currents, and the secondary storage might be a capacitor; the appliance operates with a relatively low ratio duty cycle (refrigerator). Discharging the first storage, e.g. a high capacity lead acid battery reduces storage costs. The second storage has smaller capacity but more tolerant to higher currents.

An aspect of this invention is an appliance specifically designed to enable demand shifting for another appliance or pre-defined set of appliances. The appliance comprises of a connection to household power grid (e.g. an ordinary electricity plug or a dedicated connection to ac power panel), a local storage, a micro controller, power converters to enable charge and discharge, current sensors, and a connection to another appliance or set of appliances (e.g. one or more power outlets or dedicated connection to an air conditioner). The storage is operated in a manner to achieve low consumer costs as described above.

It is an aspect of this invention to provide a user interface (UI) capable of informing the consumer of the costs and savings achieved by the demand shifting and to allow user to understand costs and savings of various cycle options and make an informed choice. In an embodiment, the appliance has its own user interface, for example a color touch screen.

Another example of the appliance's own user interface would be a two to three digit LED display that already exists in some washers and dishwashers, further adapted to display costs of various cycle options. The user would iterate over cycle options, preferably involving demand shifting, and would make an informed choice based on costs v. benefits.

In an embodiment, the UI is provided by another home computing device, e.g. a personal computer or a smartphone. An appliance, or preferably a plurality of appliances communicates with the home computing device over a digital wireless connection, e.g. Bluetooth or Zigbee. In an embodiment, the appliance actually contains an embedded web server, and the home computing device merely accesses the UI provided by the appliance using a web browser.

In an embodiment, the appliance would communicate to the server exchanging data about energy consumption, energy allocation decisions, appliance operating parameters and selected options, electricity prices, status of battery, status of appliance, etc. The home computing device would run a special application supporting the selected data exchange format and provide to the user a user interface.

The UI preferably integrates information from several appliances and provide the user with historic costs and energy consumption information for the appliance, costs of various cycle options or any need to replace storage and/or spare parts. The UI may further integrate information about usage and costs of other utility commodities (natural gas, water, heating fuel etc).

In an embodiment, the UI may further include advertising and maintenance information, for example, information that a particular appliance needs a replacement soon, and discount coupon for a store, or similar information about a specific part or consumables (battery, storage filter).

It is an aspect of this invention to provide a household energy management server. Such server would have a wired or wireless (WiFi) connection to the Internet and household LAN and another digital wireless connection to the appliances, preferably one with low power requirements and implementation costs (e.g. ANT or ZigBee).

In one embodiment, the server is in small enclosure similar to a wireless router (or integrated with a wireless router). In this case, the server would provide a UI to other computing devices by hosting a web server. In another embodiment, the server enclosure has its own screen. The server may be combined with a household thermostat. The data communication between server and appliances is similar to one described above for the appliances and home computing device and preferable standardized between different appliance manufacturers.

The server may make energy allocation decisions (charge/discharge, cycle delays, ctc) and communicate them to the appliances, or appliances can make those decisions, or user can make/override the decisions using the UI.

It is an aspect of this invention that the appliances can communicate with each other, the home energy management server, computing devices, and ancillary services (communication with ancillary services is preferable over internet). The communication between appliances and home energy management server is preferably over low power inexpensive digital wireless connection, such as Ant or Zigbee, but might use other means, e.g. data over power line.

Such communication requires some level of security. Preferably, the security is achieved using an underlying digital wireless connection pairing process, for example the appliance has a pairing button; but it can be implemented using other means, for example, a code is printed on the appliance and must be entered in the UI, or all appliances in the house must be initialized using the same security card.

An appliance having a UI may act as the user interface for appliances that do not have a UI. In one embodiment, a refrigerator acts as UI to all kitchen appliances and communicates to the server on their behalf. In another embodiment, a UI module comprises a touchscreen and that can be attached to a refrigerator door. The data exchange is preferably in XML format. In an embodiment, the SOAP (Simple Object Access Protocol) standard is used. The examples of data exchanges are provided above. The data format is preferably standardized.

In some embodiments, the appliances that have duty cycle (e.g., a microwave and a dryer) communicate to each other to synchronize the duty cycle to limit the amount of total peak current. In another embodiment, some loads are turned off during periods of very high demand by an appliance (e.g., air conditioning start up). For example, water heater can be turned off when AC is operating. This enables efficient operation in situations when AC power grid connection has limited capacity, or household is powered by local storage or co-generation facility (solar, wind, etc).

An aspect of this invention is an appliance (extension cord or smart power bar) containing a power plug for connection to an external supply, at least one power outlet, a current sensor, and a switch, preferably one current sensor and switch per power outlet. In an embodiment, the appliance further contains communication means with other appliances, computing devices, or home energy management server. In another embodiment, this appliance can contain a user interface. This appliance can be used to enable demand shifting and energy management of other appliances as follows:
By precisely metering the power consumption of each of the individual appliances connected to the power outlet and communicating with computing devices or home energy management server to enable informed demand shifting decisions by the customer.
By enabling a better configuration (in comparison with the prior art smart power bars) of various options to cut off power during standby mode using a user interface.
By cutting off power to enable demand shifting. For example, power can be cut off to a legacy fridge during the last hour of peak rate time; or power can be cut off to a legacy laptop computer to force it running of battery power during peak rate time.

An aspect of this invention is a laptop or another battery powered portable computing device (e.g. a portable gaming device or a subnotebook) that is operable according to principles of the present invention. The battery is operated to reduce consumer costs as described above, and further if the difference between high and low TOU rates is high enough to achieve reduction in consumer costs given battery deterioration, the laptop is operable to use battery power during at least a portion of peak rates even if it is connected to an AC power supply. The power management software is executed on the laptop. The software either controls a switch build in the laptop, or a switch in a smart power bar as described above. The software provides UI and cost calculations according to the principles described above.

It is an aspect of this invention that the storage operating parameters are computed by solving an optimization model; the model is designed to take into account the consumer costs as follows:
The time period to optimize is split into a plurality of time intervals, each interval is preferably between one to fifteen minutes.
There is a variable representing each of the consumption and storage currents for each interval. There are inequality constraints to make currents non-negative when appropriate. There are further equality constraints to represent Kirchhoff's Law.
There are costs associated with drawing currents from the power grid according to the TOU rates schedule.
There is a variable representing the amount of energy stored in the storage for each interval. There are inequality constraints to provide that those amounts are above zero and below the storage capacity. There are equality constraints linking those amounts in adjacent time intervals taking into the account the storage self-discharge rate, other losses, and charge/discharge currents.
There are costs or premiums associated with the energy stored in the storage at the end of the time period to optimize.
There are costs or premiums associated with the battery deterioration/recovery during the time period to optimize.
The user needs and preferences are represented by constraints (e.g. the refrigerator compartment must stay within a predetermined temperature range or clothes need to be dried by specified time). In some embodiments, those constrains are integrated into the cost function with appropriate coefficients.

It is an aspect of this invention that various charging and discharging techniques aimed at reducing consumer costs can be integrated in the optimization model. For example, it could be a charging method which is variable in a binary or integer fashion (use pulse or normal charge). If pulse charging is used, the amount of energy used increases insignificantly, but the battery deterioration costs are decreased more significantly.

It is an aspect of this invention that various charging and discharging techniques aimed at reducing consumer costs are pre-programmed into the controller to be executed when specified conditions are met and are not part as of the optimization model.

In some embodiments, the solution of the optimization model is found by the integrated microcontroller or the energy management server or a home computing device. In other embodiments, the solution is found during the design time and simple algorithm is executed by the microcontroller. In some embodiments, a combined approach is used—during design time, a fixed number of scenarios with limited number of parameters are determined, and the microcontroller decides on specific scenarios and parameters values.

### BRIEF DESCRIPTION OF THE DRAWINGS

FIG. 1a is an illustration of the cost calculation and using consumer costs as a basis to select an economical appliance cycle.

FIG. 1b is a block diagram of the appliance with primary and secondary electrical storage.

FIG. 1c is an alternative block diagram of the appliance with primary and secondary electrical storage.

FIG. 2 is a block diagram of the appliance with single electrical storage.

FIG. 3 is a block diagram of the appliance embodied as a separate power supply with electrical outlets.

FIG. 4 is a block diagram of the appliance embodied as a refrigerator with DC compressor.

FIG. 5 shows an exemplary view of the UI to input a TOU rate schedule.

FIG. 6 shows a plurality of household appliances receiving from a household computing device time of use rate schedule information and/or energy allocation decisions and sending to the same household computing device energy use information.

FIG. 7 shows the reception of a TOU rate schedule from the Internet by ??????

FIG. 8 shows a block diagram of the battery subsystem with a lead acid battery and a super capacitor.

FIG. 9 is a timing diagram showing the low current charging of a secondary by a primary. storage and subsequent quick discharge of the secondary storage.

FIG. 10 shows a timing diagram of a refrigerator having sufficient battery capacity to charge during period of low energy prices and discharge during periods of high energy prices.

FIG. 11 shows a timing diagram of a refrigerator achieving consumer cost reduction by keeping the battery charged as much time as possible, that is suitable for example, for lead acid batteries.

FIG. 12 shows a timing diagram of an refrigerator achieving consumer cost reduction by keeping battery discharged as much time as possible, that is suitable for example, for ZEBRA batteries.

FIG. 13 shows the use of partial and full discharging to condition a battery

FIG. 14 shows change in the patterns of functioning of the fridge as the battery deteriorates

FIG. 15 shows a front view of the appliance embodied as a separate power supply with electrical outlets.

FIG. 16 shows a central air conditioner adapted to work according to the invention.

FIG. 17 shows an appliance designed as a field upgrade for a pre-existing central air conditioner to adapt the air conditioner to work according to the invention.

FIG. 18 shows a refrigerator designed to work according to the present invention.

FIG. 19 shows a timing diagram illustrating use of utility power for periods of short term, high current demand during periods where appliance normally runs off storage power.

FIG. 20 illustrates an optimization model that can be used to reduce consumer operating costs.

FIG. 21 shows a household thermostat adapted to control appliances according to the present invention.

FIG. 22 shows a household energy management server interacting with appliances, computer, and the ancillary services

FIG. 23 shows a smart power bar adapted to practice the present invention and a laptop computer adapted to practice the present invention by software.

FIG. 24 shows an example of a household energy management user interface designed according to the present invention.

FIG. 25 shows a washer/dryer pair designed according to the present invention and interacting with a household energy management user interface according to the present invention.

FIG. 26 depicts appliances communicating to synchronize their duty cycles to reduce total demand.

FIG. 27 depicts a timing diagram for a group of appliances communicating to synchronize their duty cycles to reduce total demand.

FIG. 28 illustrates the scenario with continuously changing TOU rates.

FIGS. 29-40 illustrate various charge/discharge scenarios.

### DETAILED DESCRIPTION OF THE INVENTION

The following numbers are used in the drawings:

| | |
|---|---|
| 101 | External Power Supply |
| 102 | Load |
| 103 | Power Switch |
| 104 | Energy Storage |
| 105 | Storage Switch |
| 106 | Controller |
| 107 | Interface |
| 108 | Storage Sensor |
| 109 | Charger |
| 110 | Charge Converter 1 |
| 111 | Discharge Converter 1 |
| 112 | Energy Storage 1 |
| 113 | Charge Converter 2 |
| 114 | Discharge Converter 2 |
| 115 | Energy Storage 2 |
| 116 | Digital wireless communication |
| 117 | AC power cord |
| 118 | AC outlet |
| 119 | Touchscreen Interface for entering of Time Of Use |
| | rates and schedule |
| 120 | Compressor unit and other power consuming subsystems |
| | of the refrigerator |
| 121 | Controller with PWM driver |
| 122 | TV set |
| 123 | communication link |
| 124 | communication link |
| 125 | washing machine |
| 126 | communication link |
| 127 | dish washer |
| 128 | Refrigerator |
| 129 | connection to a power supply system or power grid |
| 130 | connection to energy consuming load |
| 131 | energy storage subsystem |
| 132 | connection to the Internet |
| 133 | communication device |
| 134 | power shifter |
| 135 | Air Conditioner |
| 136 | molten sodium aluminum chloride secondary battery |
| | (ZEBRA battery) |
| 137 | household thermostat |
| 138 | power grid connection box |
| 139 | energy storage subsystem compartment |
| 140 | other electronic unit |
| 141 | refrigeration compressor |
| 142 | Other loads in refrigerator |
| 143 | Discharge controller/converter |
| 144 | Smartphone |
| 145 | digital wireless |
| 146 | Zig-bee |
| 147 | PC |
| 148 | Web |
| 149 | Gadget |
| 150 | Laptop computer |
| 151 | Laptop battery |
| 152 | Energy Management Software |
| 153 | Laptop Power Adapter |
| 154 | Smart Power Bar |
| 155 . . . 159 | Current Sensing Circuit |
| 160 . . . 165 | Power Outlets |
| 166 | Power Bar Controller |
| 167 | Communication Link |
| 168 | Washer |
| 169 | Dryer |
| 170 | Laundry weight sensor |
| 171 | Cycle controls |
| 172 | Costs display |
| 173 | wired communication link |
| 174 | humidity sensor |

Background Information about Battery Chemistries

This section provides background information according to the understanding of the inventors. The invention is embodied to reduce storage portion of the consumer costs according to the information in this section. More sophisticated and precise battery models, as well as progress in battery technology will provide different embodiments of the present invention.

There are a variety of possible battery technologies to choose from for electrical storage and demand shifting, each with its own peculiarities. Table 1 summarizes the characteristics of various battery technologies. Average charging efficiency is defined as the efficiency of charging from a zero State Of Charge (SOC) to typical test value (typically 91%). Incremental charging efficiency is defined as the efficiency of charging between two non-zero SOC's, for example, 79% and 84%.

| | | | Average | Incremental |
|---|---|---|---|---|
| | lifetime (100% | lifetime - 45% | Charging | Charging |
| Type | discharge) | discharge | Efficiency | Efficiency |
| Lead Acid | 200 | 500 | 91% (to 84% | 55% (79% to |
| | | | SOC) | 84%) |
| NiMH | 300¹ | 300¹ | 65%² | 65%² |
| NiCd | 500 | 3000 | 71%-91%³ | |
| NaNiCl | 1000-3000 | 1000-3000 | 90%⁴ | |
| (ZEBRA)⁴ | | | | |
| LiOn⁵ | 1000 | 1000 | 90% | |

¹battery capacity lost after 300 cycles is 50%. This type of battery has a high self discharge rate
²the charge/discharge efficiency for NiMH batteries is 65% for any charge/discharge depth.
³The charge efficiency factor of a standard NiCd is better on fast charge than slow charge. At fast charge rate, the typical charge efficiency is 91 percent. On an overnight slow charge, the efficiency drops to 71 percent. Once the 70 percent charge threshold is passed, the battery gradually loses ability to accept charge.
⁴Zebra (NaNiCl or molten salt batteries) can be characterize as follows: the expected life time is 1,000-3,000 charging cycles. The overall battery charge/discharge efficiency is 90%. This battery has an extremely high self discharge rate ~14% per day. Battery shall be operated at relatively high temperatures.
⁵LiOn batteries can be characterized as follows: expected lifetime is 1000 cycles or 3-5 years (whichever comes first). The overall battery charge/discharge efficiency is 80-90%. Battery lifetime can be increased by operating and/or storing battery at lower temperatures.

There are opportunities to optimize the power efficiency of appliance in both the storage charge and discharge operations. In the charging operation, a significant portion of the “cheap” off peak input energy may be lost and never stored if a battery is charged beyond a certain threshold. For example, in Table 1, a typical lead acid battery has a storage efficiency of 91% when charged from 0% SOC to 84% SOC but only 55% efficiency when charged from 79% to 84%. Thus, 45% of the input power is lost when charging a lead acid battery from 79% to 84%. In one embodiment of the invention then, power efficiency and cost reduction are achieved by the appropriate choice of a peak charging value. Battery capacity is strongly affected by discharge characteristics according to the well known Peukert's law. Capacity increases with decreasing discharge currents according the formula:

$$It = {C ( \frac{C}{IH} )}^{k - 1}$$

It is the effective capacity at the discharge rate I;
I is the variable discharge rate;
is the nominal battery capacity
H is rated discharge time (usually 20 hours)
Thus, it is beneficial to discharge a battery at a low discharge current to make the most efficient use of the stored energy.

### DESCRIPTION OF VARIOUS EMBODIMENTS OF THE INVENTION

Energy efficiency and cost reduction can be achieved by appropriate control of the storage discharge. Therefore, in one embodiment of the invention, discharge control is achieved by coupling the battery with a secondary storage device capable of high discharge currents such as a capacitor or ultra capacitor. The capacitor augments the battery by providing additional current capacity during high current demand periods.

In another embodiment of the invention the capacitor acts as the primary current source to the load. The capacitor is slowly charged from the battery during idle periods when there is no current demand such as may occur in a refrigerator between compressor cycles.

In another embodiment of the invention, the external electrical supply is used to supplement the battery during high current demand intervals and keep the battery discharge current to an appropriate level.

Battery lifetime is also affected by the discharge characteristics. For instance, the life time of a lead acid battery subject to 100% discharge is only 200 cycles while the lifetime of a battery subject to only 45% discharge is 500 cycles.

In one embodiment of the invention, storage lifetime is improved by using the external electrical supply to supply power even during peak periods should the storage discharge beyond a level that will appreciable affect its lifetime. The prior art describes use of the external power supply during peak periods but only to prevent power failure of the battery.

Battery lifetime can also be improved by the use of periodic maintenance cycles. For instance, although the continual, 100% discharge of a lead acid battery decreases it's lifetime, periodic “deep discharge” maintenance cycles are beneficial. In another embodiment of the invention, storage lifetime is improved by periodically allowing the battery to discharge to maintenance levels during normal operation. Information describing periodic maintenance procedures which prolong a battery life could be downloaded from: http://batteryuniversity.com/. It is recommended to perform a periodic deep discharge every month.

It is anticipated that a large range of existing and installed electrical appliances will benefit from the inventive concepts disclosed herein. Therefore, in another embodiment of the invention, an existing electrical appliance can be connected to the invention through means such as an A.C. plug and the invention may or may not perform any function other than demand shifting.

In some jurisdictions, there are multiple TOU electrical billing rates that are confusing to the consumer. In another embodiment of the invention, the appliance receives regular information about TOU rates and any changes therein from a remote server without requiring any action on the part of the consumer.

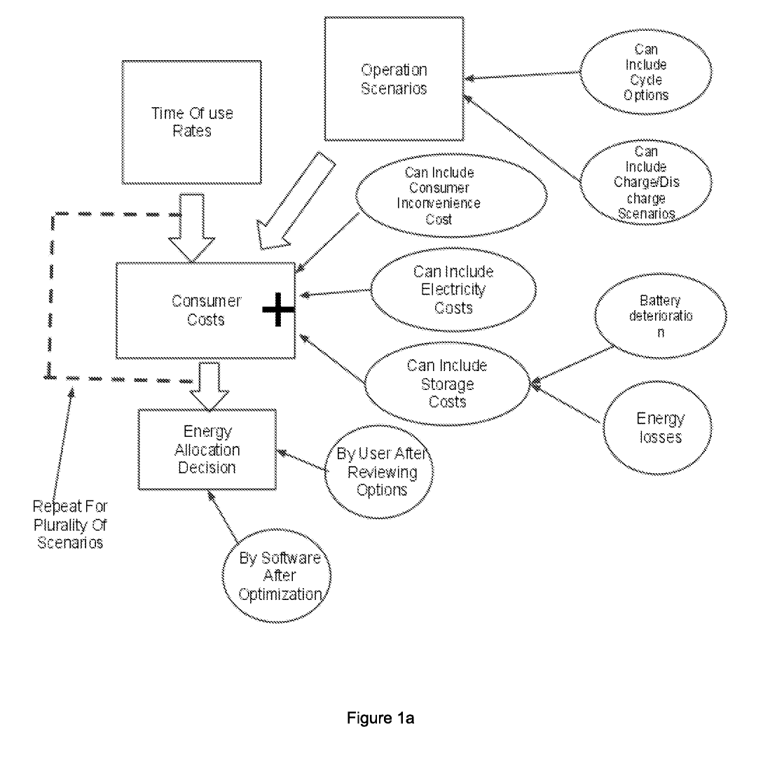

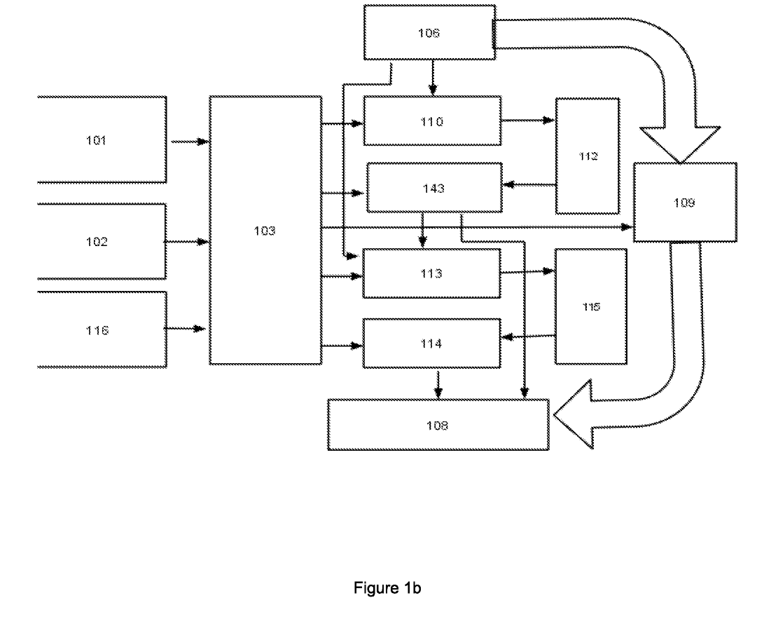

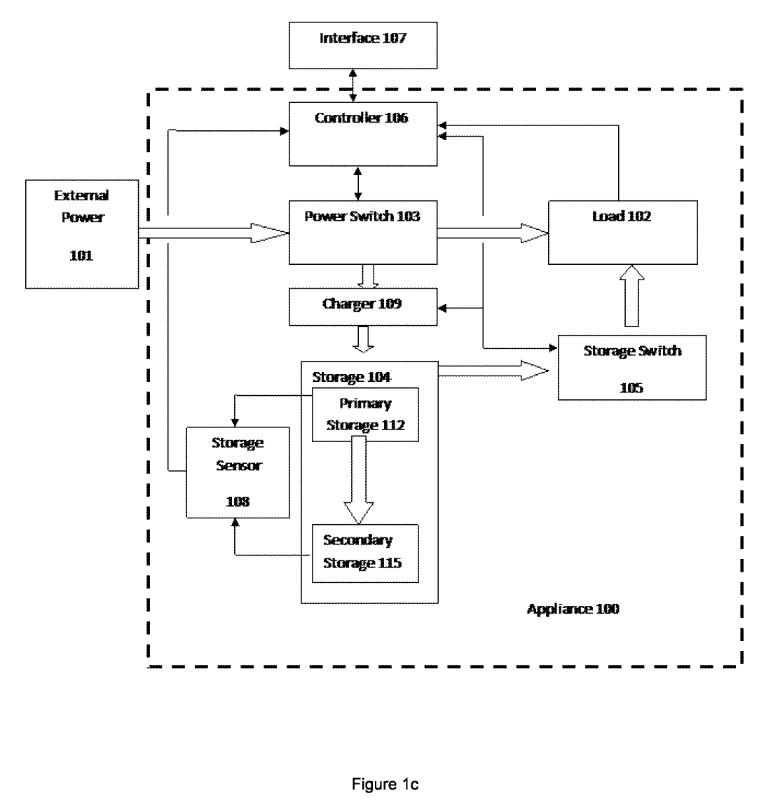

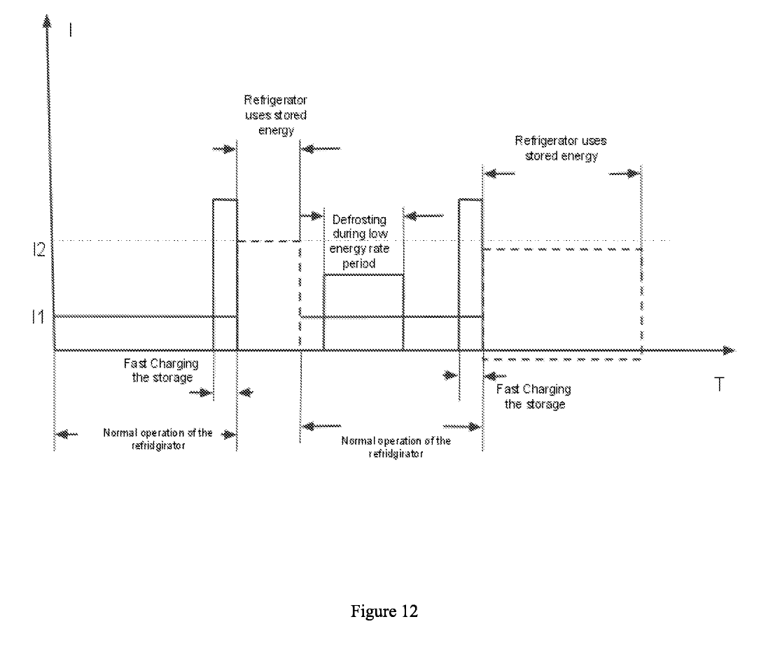

FIG. 1a depicts the process of cost computation according to the principles of the invention. Let us assume that a time interval is split to N smaller time intervals, N>0. An appliance use scenario involves receiving from the household power grid electrical energy Pᵢ≧0 at the time interval i, 0≦i<N. For an actual appliance past use scenario values of Pᵢ can be either directly measured by a current sensor, or computed by the micro-controller from appliance operating parameters. When the use scenario is anticipated, the values of Pᵢ are computed according to the specific parameters of the use scenario which might include: anticipated appliance cycle options and needs and taking into account available information, for example, dryer load size received from the washer, dirt level of the dishes, anticipated room temperature and number of anticipated door openings for a fridge, etc. In an embodiment, the “baseline” use scenario for an appliance can be identified for an appliance. Baseline scenarios are scenarios when some energy saving or demand shifting features are not used. Only practical scenarios in which the appliance can actually perform its utility function are considered in this invention. In the known art, impractical “use only the cheapest TOU rate scenario” were considered without regard to being able to actually perform utility function (see FIG. 12 in Finch). Cost computation can be performed on one or more of the following types of usage Actual historic usage events over one or more time intervals,
Anticipated use scenarios, with specific cycle options, timing, or internal operating mode, including using the electrical storage.
Baseline “status quo” scenario corresponding to a historic or anticipated use scenario, but with other options, for example without using electrical storage or without using demand shifting.

The cost of electricity received from the power grid can be computed using the formula

$$E = {\sum }_{i = 0}^{i < N} {c}_{i} {P}_{i} ,$$

where cᵢ be the historic or anticipated time of use electricity price during the time interval i. The splitting of the appliance use time “T” into time intervals is preferably done in a way that there is only a single time of use rate during an interval. In alternative embodiments, average or prevailing rates can be used.

When the appliance contains electrical storage, extra variables are introduced: let Mᵢ be an integer variable indicative of the mode the storage is being charged or discharged in (no use of storage, maintenance charge/discharge, normal charge/discharge, pulse, etc), let Dᵢ be the average discharge current during the i-th time interval (negative current is indicative of the charge). Then one can define the amount of the energy present in the storage at the beginning of the i-th time interval. In the simplest way, this amount is defined as:

Sᵢ=αSᵢ₋₁−βDᵢ₋₁,

where α, 0≦α≦1 is a value indicative of the storage self-discharge rate, and β is value indicative of charge/discharge cycle efficiency. However, in most embodiments the actual equation for Sᵢ a more sophisticated non-liner equation depending on both Sᵢ₋ᵢ and discharge mode and taking into the account both battery chemistry, laboratory testing of a specific battery model, and analysis by a micro-controller on the appliance of historic charge and discharge cycles. For example, approaches disclosed in:
“A mathematical model for lead-acid batteries”, Salameh, Z. M.; Casacca, M. A.; Lynch, W. A.; IEEE Trans on Energy conversion, 1992, Vol 7, Issue 1;
“Accurate electrical battery model capable of predicting runtime and I-V performance”, Min Chen; Rincon-Mora, G. A.; IEEE Trans on Energy conversion, 2006, Vol 21, Issue 2;
U.S. Pat. No. 5,596,260 to Moravec et al;
U.S. Pat. No. 6,242,891 to Parsonage;
U.S. Pat. No. 5,596,262 to Boll;
   can be used. All the references are incorporated herewith by reference.

Another component of the cost function is the cost of the electricity which has been added to or removed from the storage. It can be defined as

Δ= c̅(S₀−S_{N}),

where c̅ is the prevailing time of use electricity rate to be received by the appliance till the completion of the next charge cycle. Δ can be estimated given anticipated appliance use, for example using historic use. To reduce the level of subjectivity in cost calculations, some embodiments may prefer to use scenarios where S₀≈S_{N}. When the time interval is long (for example, a month or larger), Δ<<E and Δ can be ignored.

Another component of the cost function is battery deterioration costs. Let Lᵢ be the ratio of total recoverable battery storage capacity at the beginning of i-th time interval to the originally available battery storage capacity. Lᵢ can dependent on Lᵢ₋ᵢ, current and/or charge/discharge methods used during i−1-th time interval and/or previous time intervals, hidden variables describing battery internal state, temperature, etc.

It is desirable to dispose battery once the available storage is too low. In some embodiments, Lᵢ can be defined be the ratio of total recoverable battery storage capacity that minus the “dispose” threshold at the beginning of i-th time interval to the originally available battery storage capacity minus the “dispose” threshold.

The technique used to compute Lᵢ depends on the Computing resources and the battery chemistry and design. For example, techniques described in
“A mathematical model for lead-acid batteries”, Salameh, Z. M.; Casacca, M. A.; Lynch, W. A.; IEEE Trans on Energy conversion, 1992, Vol 7, Issue 1;
“Accurate electrical battery model capable of predicting runtime and I-V performance”, Min Chen; Rincon-Mora, G. A.; IEEE Trans on Energy conversion, 2006, Vol 21, Issue 2;
U.S. Pat. No. 7,711,426 to Armstrong et al;
U.S. application Ser. No. 10/612,080 by Kim et al
   can be used. All the references are incorporated herewith by reference.

The invention advantageously monitors Lᵢ or a similar value indicative of the remaining battery capacity or lifetime, informs user about battery the value lifetime or need to replace battery, uses the value to plan charge/discharge cycles, and optimizes battery operation to reduce the deterioration.

Let Qᵢ be the total amount of electrical energy needed to be received by the appliance and to be used for maintenance charge/discharge cycles. Then the battery deterioration costs can be defined as

B=(L_{N}−L₀)W+ĉ(Q_{N}−Qₒ),

where W is the replacement cost of the battery

The total costs are defined by the formula

C=E+B+Δ

The costs defined using this formula includes electricity losses due to charge, discharge and voltage conversion (as all electricity received from the grid is accounted in the E term). This is done using the coefficient β above or using a more sophisticated non-liner model for Sᵢ.

The costs defined using this formula includes electricity losses due to the self discharge. This done using the coefficient α above or using a more sophisticated non-liner model for Sᵢ.

The formulas for cost computations above are exemplary only. Actual embodiments may use different techniques to compute costs. Some embodiments will use more precise battery models. Some other embodiments will use approximations for non-linear terms such as Lᵢ, Sᵢ, Qᵢ.

The costs related to battery operations can be viewed as having the following components:
Charge/discharge and power conversion losses, accounted for by the coefficient β introduced above or using a more sophisticated non-liner model for Sᵢ.
Cycle costs, defined as battery deteriorations costs represented as a fixed amount per each cycle.
Storage costs, defined as having the following components:
   Battery self-discharge costs, accounted for using the coefficient α introduced above or using a more sophisticated non-liner model for Sᵢ
   Battery deteriorations costs associated with battery staying at a charge state particular time (accounted by Lᵢ).
   Battery deteriorations costs (can be negative) associated with charge/discharge method and/or current level (accounted by Lᵢ).

The art, such as Miller, teaches use of charge/discharge losses and cycle costs to optimize storage energy allocation decisions. Energy allocation decisions according to the art will not schedule charge or discharge operations to reduce storage costs. Further, the art will not be able to select the optimum current to balance energy losses and battery deterioration due to current level and energy costs. Use of storage costs in the invention advantageously impacts scheduling and selection of charge level to prolong battery life. Use of plurality of charge modes and non-linear model for Sᵢ advantageously allows use of optimized charge mode, current, and level.

A general diagram of an embodiment of the invention is shown on FIG. 1b. Power flow in the figure is indicated by thick arrows and control/sensor information flow by thin arrows. Power flow between external power supply 101 and load 102 is controlled and time shifted to minimize overall system operating costs. In some embodiments, external power supply 101 is AC utility power. Load 102 can be supplied with power directly from external supply 101 through power switch 103. Power may also be supplied to load 102 from storage 104 through storage switch 105. Storage 104 is charged by external power supply 101 through power switch 103 and charger 109.

In one embodiment, storage 104 consist of a single electrical storage element such as a battery.

In another embodiment, storage 104 consists of primary storage 112 and secondary storage 115, as shown in FIG. 1b.

In some embodiments, primary storage 112 may be a lead acid battery. Lead acid battery capacity and lifetime can be improved by discharging at low currents. The secondary storage 115 is chosen to more tolerant to high current loads and may be a capacitor or super capacitor.

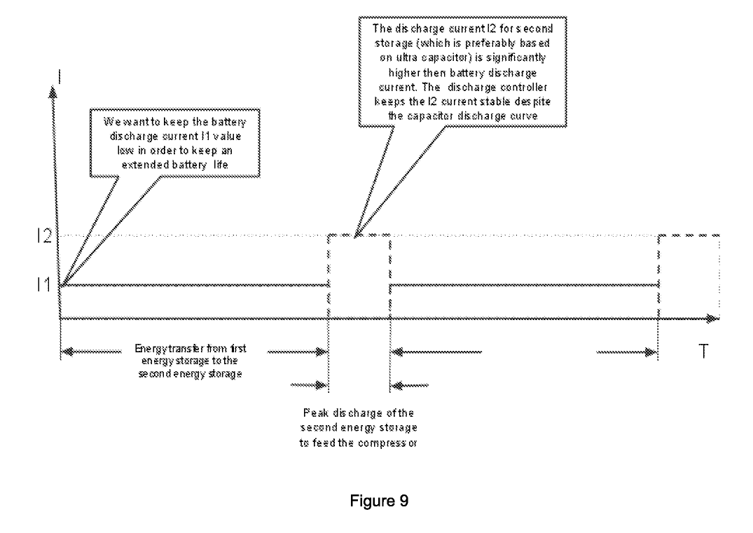

In some embodiments, first energy storage 112 is continuously charging the secondary storage 115, which is then discharged at higher currents to accommodate a load with a high current but intermittent power demand (e.g., to run a refrigerator compressor). A simplified graph of power output to load 102 in this embodiment is shown in FIG. 9.

Controller 106 controls the process of charging/discharging the energy storage through switches 103 and 105 respectively. Controller 106 also controls the direct connection of load 102 to external supply 101. In some embodiments, the Controller might be a relatively low computing power device such as an 8-bit Atmega 128 MCU (Micro-controller) made by Atmel Corporation. In another embodiment, the Controller is a custom designed ASIC (Application Specific Integrated Circuit). In another embodiment the controller may be a Field Programmable Gate Array (FPGA) such as manufactured by Altera Corporation.

The controller minimizes the system operating cost by optimally allocating power to the load from external supply 101 and storage 104 and by optimally charging storage 104.

In some embodiment the controller may use special charge/discharge modes (deep/shallow charge/discharge, high or low current, impulse charge etc to reduce battery memory effects or otherwise extend battery life and efficiency.

In some embodiments the controller has software to make these power allocation decisions. In another embodiment the logic for these control functions may be implemented in hardware. In another embodiment the logic is implemented as the programming code for an FPGA.

The controller receives the external information (such as time of use rates) needed to make optimal power allocation decisions using interface device 107.

In one embodiment, the interface device is a keypad or touchscreen connected to the controller. In another embodiment the interface device is a keypad or touchscreen wirelessly connect to the controller.

In another embodiment, the interface device is an internet enabled remote computing device such as a PC, tablet or smartphone. In this embodiment, Controller 103 supports a web server that a user can access over the Internet to manage the appliance remotely. In such embodiments, the controller 103 is typically an advanced MCU such as the Cortex M3 based MCU manufactured by NXP.

In another embodiment, the interface device is a separate home energy management appliance, or energy management controller integrated into a household energy meter and connected to the controller by a home network such as wireless or wired LAN.

Controller 106 receives the necessary internal information (such as charge state of the storage or power demand of the load) to make power allocation decisions from battery sensors/controllers 104 and switches 103 and 105 and load 102

In one embodiment of the invention, the storage, controller, switches and sensors are integrated with the load into a single appliance as shown by the dotted line in FIG. 1a.

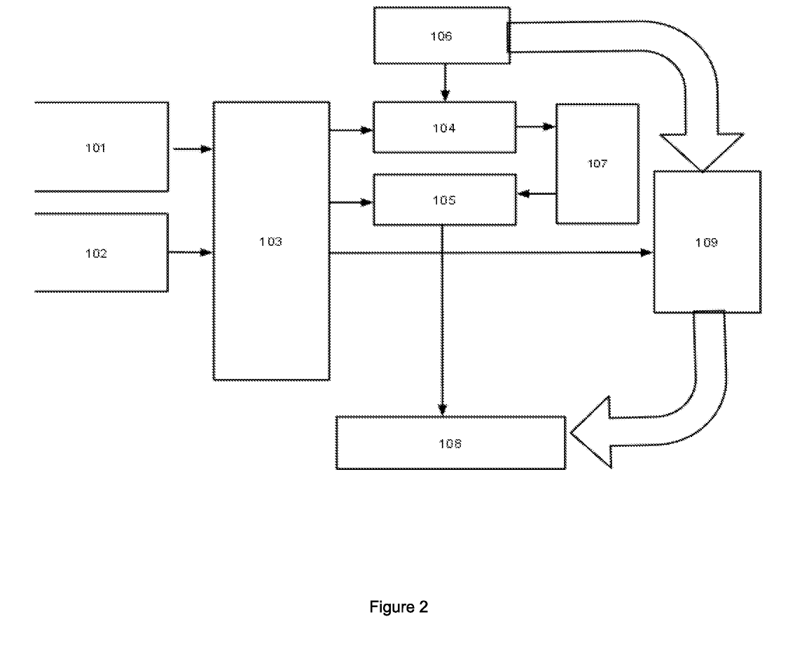

FIG. 2 shows a simplified version of FIG. 1 with only primary energy storage. This version would be suitable for purely resistive loads without high start up current demands (such as an electric water heater) or for battery types like the ZEBRA batteries that can support high discharge currents.

In another embodiment of the invention, the storage, switches, controller and sensors are a separate appliance, to which an external electrical appliance is connected by means of an ordinary electrical plug and power cord or the like. This version of the invention is intended to meet the needs of pre-existing, installed appliances.

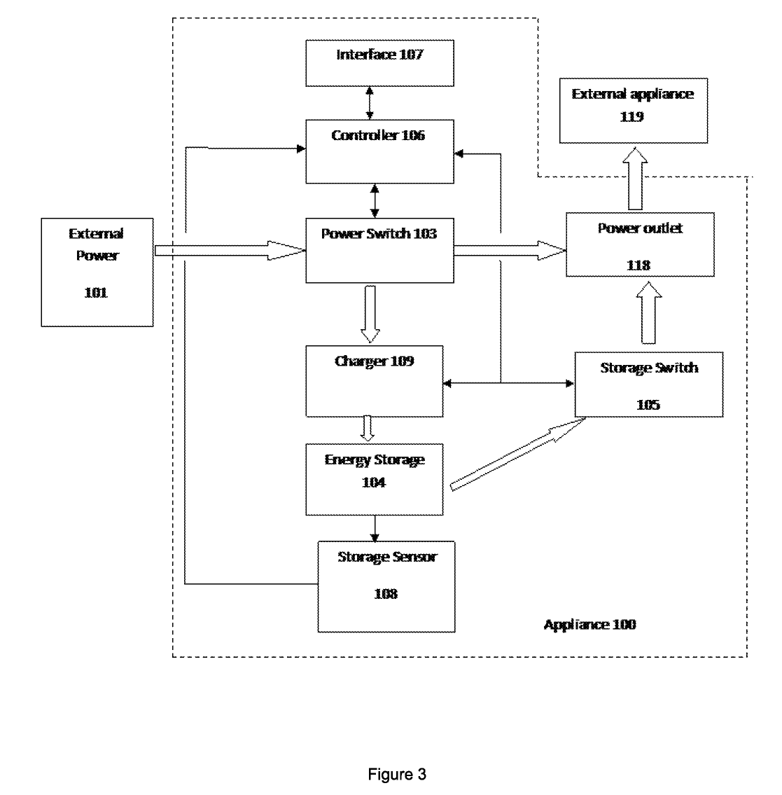

FIG. 3 shows a block diagram of this “power shifter” embodiment. Power energy is supplied to the power outlet strip 118. Power outlet strip 118 may conform to any one of a number of standard electrical outlet types. Strip 118 may contain a single outlet socket or multiple sockets for the connection of multiple external appliances. The power shifter nicely enhances value of “smart power bars” currently available on the market.

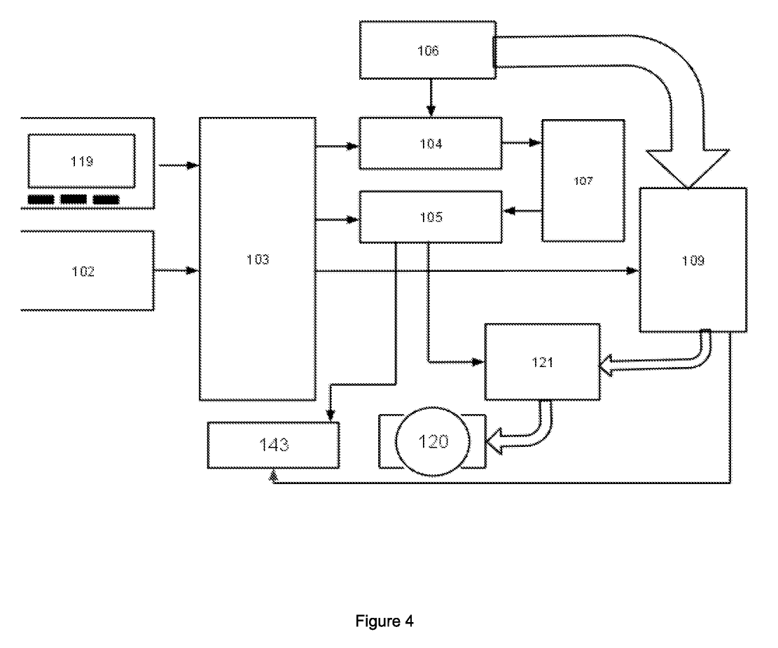

In one embodiment, shown in FIG. 4, the appliance is refrigerator, freezer or similar cooling unit. Brushless DC motor 120 is supplied with power through motor controller/converter/PWM 121. To limit damage to the battery caused by high startup current of the motor, motor controller/converter/PWM can use both storage battery power and external power connection 109 on start-up, even during peak demand times. In one embodiment touchscreen interface 119 is used to enter and display the TOU rates and schedule. In another embodiment the touchscreen interface is integrated into the general appliance User Interface (UI) which performs other functions such as reminders to replace a water filter, shopping list, etc.

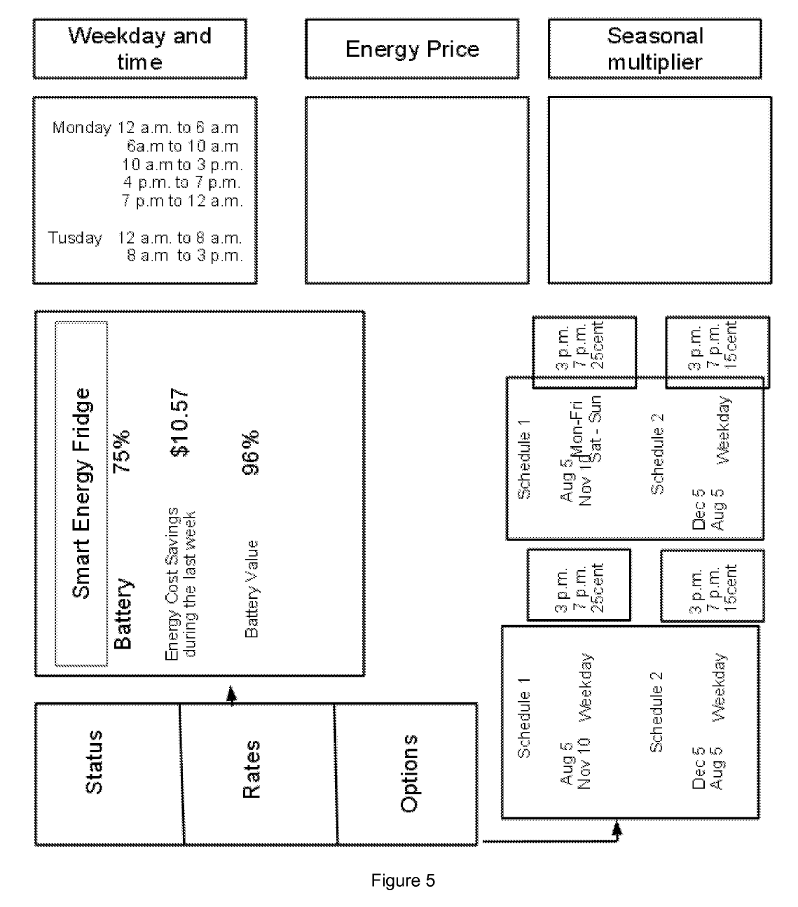

FIG. 5 shows an exemplary UI. TOU rates and schedule can be entered manually or retrieved and displayed from a server. There are screens to display the amount of electricity used and amount saved due to TOU demand shifting. There are also screens to display battery status. In an embodiment, the user interface can be organized do manage several appliances.

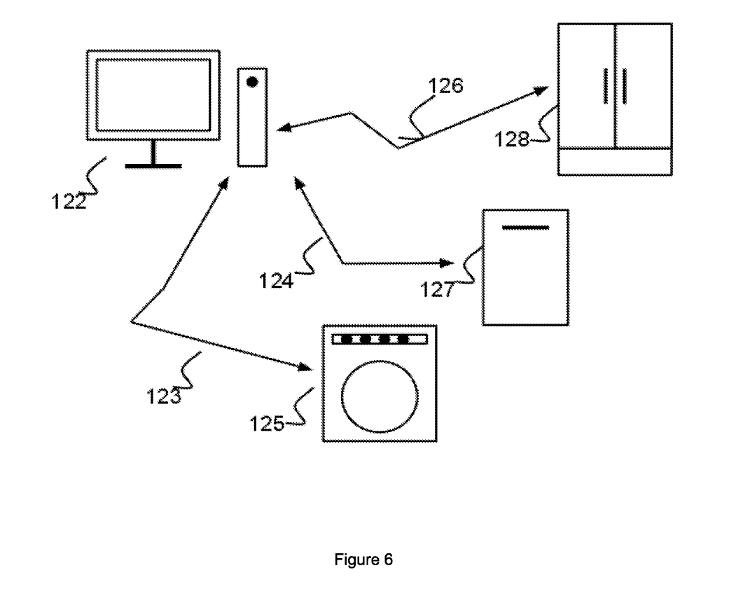

FIG. 6 shows various appliances 125, 127, 128 connected to a computing device 122 using communication links 125, 127, 128. The computing device can be a multi-purpose computing device such as a personal computer, smartphone, or tablet or it may be a dedicated energy management appliance. The communication link can be implemented using a wireless standard such as Bluetooth, Zigbee, Ant, Wifi, IR or other or as a wired connection using data over power line, Ethernet, I2C, etc.

In this embodiment, the time of use rates and schedule are entered once on a remote computing device, and sent to the different appliances.

In another embodiment, the appliances can also communicate in peer to peer mode. For example, an appliance might be too far from the computing device for a reliable or energy efficient wireless connection. In this case, another appliance can re-transmits the information. In another example, an appliance with a UI can be used to enter TOU rates and schedules and otherwise control an appliance without a UI. In a washer/dryer pair, for example, a washer may have a touchscreen UI, while the dryer does not. In another example, a refrigerator with Ul might be used to enter TOU rates and schedules and otherwise control other kitchen appliances, for example, by providing UI to select dish-washing options.

Some appliances can be implemented in interface less mode, where they receiving time of use information from the computing device 122 or interface enabled appliances. In some embodiments, the computing device 122 or interface enabled appliance makes some of the energy allocation decisions, and transfer them to other applainces over the links 125, 127, 128.

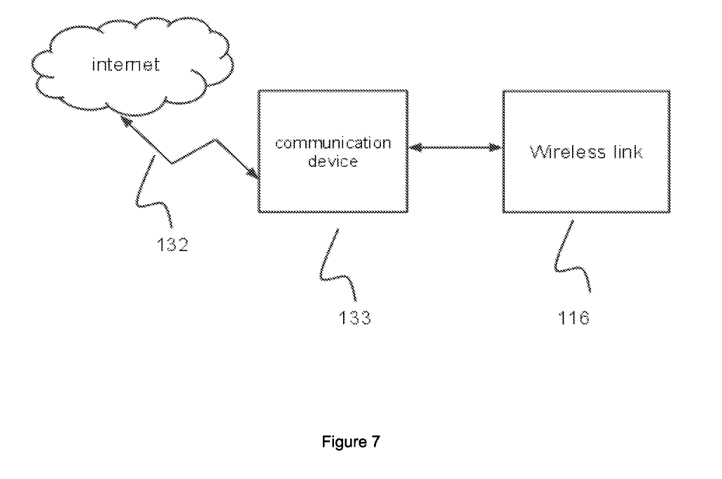

In some embodiments, information such as time of use rates, the peak/off peak conditions, and external information such weather forecast is obtained from an Internet server. This process is shown on FIG. 7. In some embodiments, a proxy communication device 133 retrieves this information and distributes the information or energy allocation decisions over wireless link 116. In another embodiment, appliance can directly communicate with the Internet server using WiFi link. In an embodiment, the appliance communicates energy use and savings information to an Internet server.

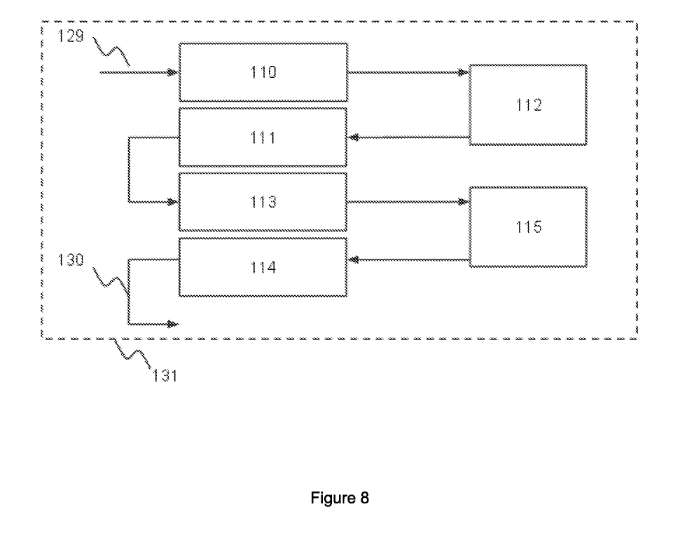

FIG. 8 shows an energy storage subsystem 131 of the appliance. In some embodiments, it can be implemented as either a separate replacement module, or in a separate stand alone enclosure.

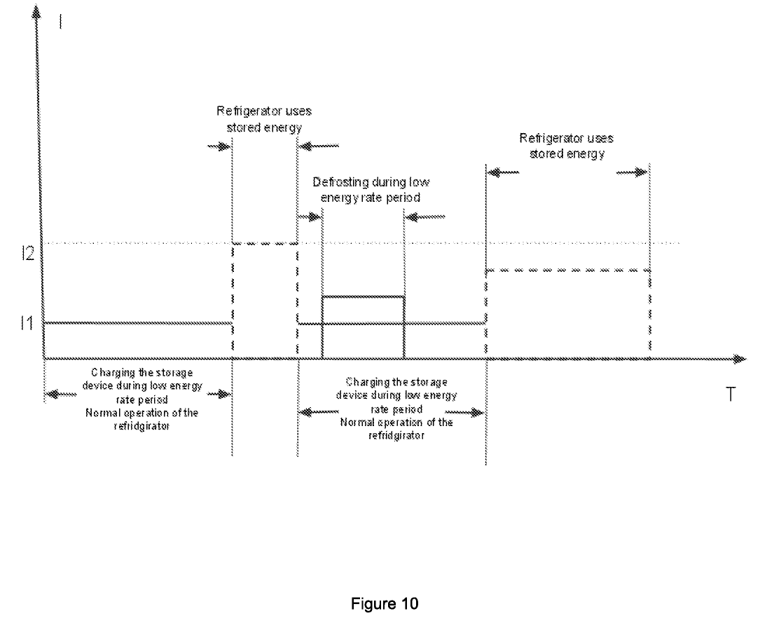

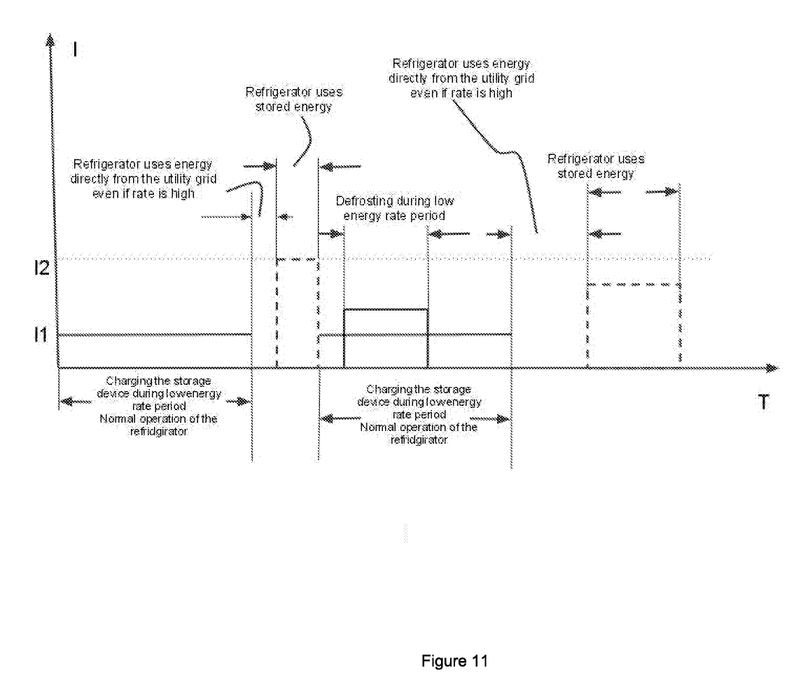

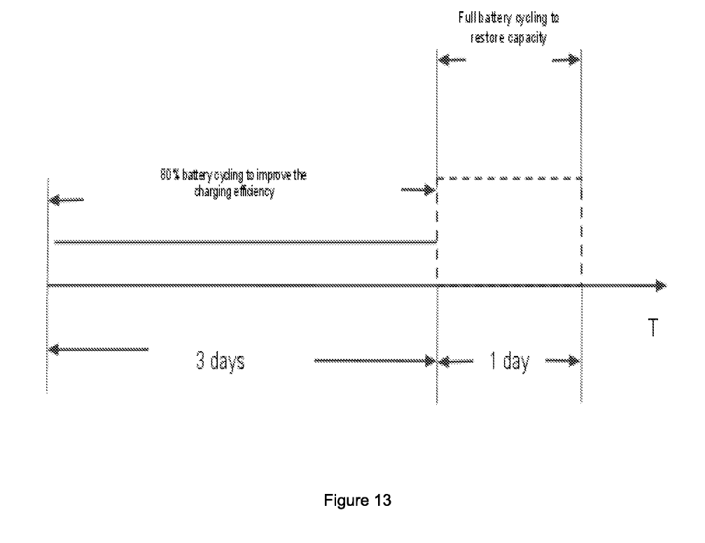

FIGS. 9-13 shows various energy allocation decisions depending on battery type and specific appliances. For some batteries, for example Zebra battery or LiOn it is costly (detrimental to battery life, capacity, or the stored energy) to keep the battery charged. For another batteries, for example lead-acid or NiCd, its is costly to keep battery non-charged. Some batteries prefer high current charge, some batteries prefer low current charge. From time to time, an energy allocation decision to perform specific operation to increase battery life or remaining capacity can be made. Such operations can include charge or discharge with optimum constant current, use of pulse charge or discharged with duty cycle, where duty cycle is determined taking into the account battery chemistry and design. Other activities may include periodic short-term charges with over voltage. Such charges are normally called a normalization charges.

Individual batteries and individual cells within lead acid batteries react differently to be charged. Over time battery performance will drop as differences become more pronounced. At this stage it is necessary to perform an equalization charge (or refreshing charge)—usually once every 10 cycles, at least once per month, or when the range of voltages across the battery bank's batteries is over 0.30 volts.

An equalization charge must only be performed on vented (not sealed) wet lead acid batteries. An equalization charge is a current-limited charge carried out at higher voltages than normal in order to bring all cells within all batteries to 100% charge. A typical lead acid battery charger uses a fixed charging voltage of 13.6 volts in day to day operation. During equalization this charging voltage is increased to 14.4 volts and higher ensuring that all cells receive the current necessary to get them fully charged.

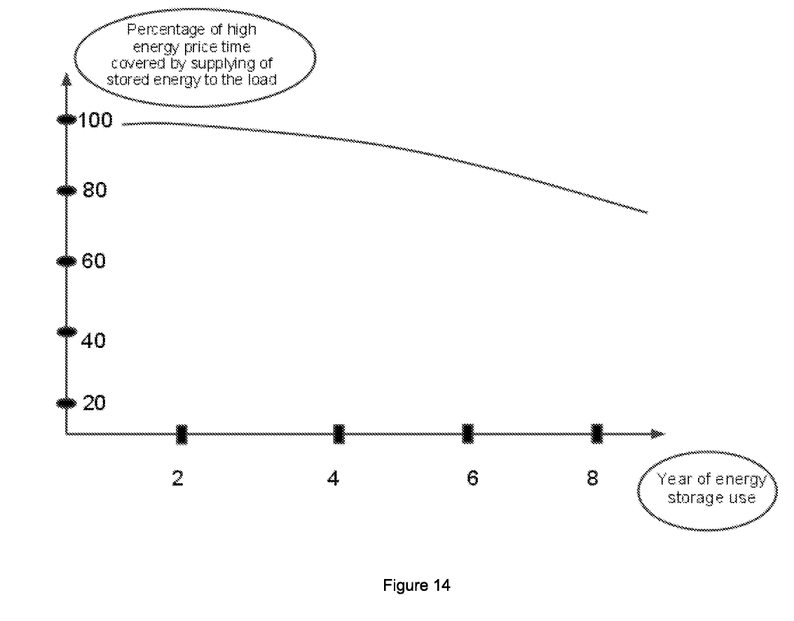

FIG. 14 shows how electrical storage capacity deteriorates over time. In an embodiment, the invention computes or measures the remaining capacity of the battery or a value indicative to the remaining capacity of the battery such as Lᵢ introduced above. The invention can advantageously change charge or discharge mode or scheduling to optimize the battery usage given the remaining capacity.

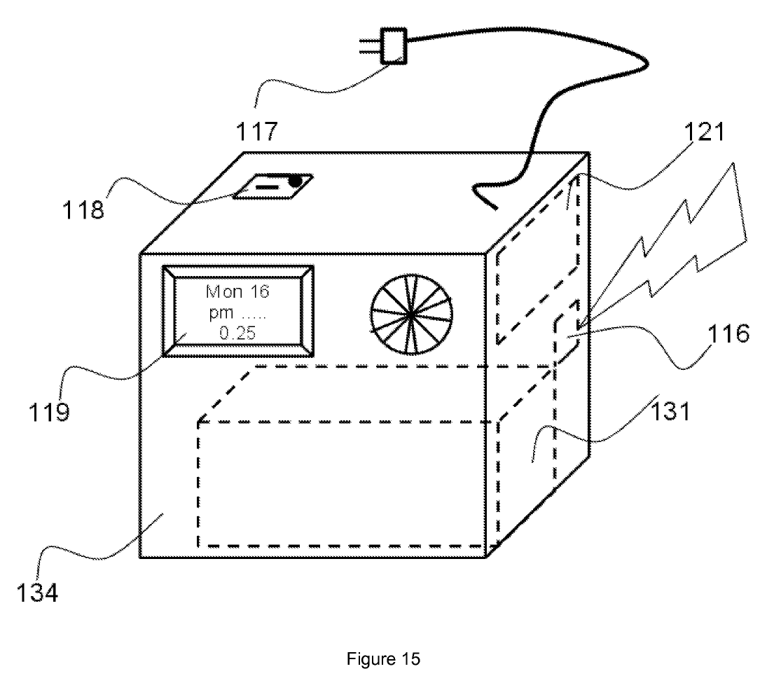

FIG. 15 shows the invention embodied as a separate device designed to enable demand shifting for a household utility appliance that normally receives energy by plugging into a power outlet. The invention receives the electrical energy using power cord 117. Another utility appliance can be plugged in using outlet 118. Invention can have a plurality of power outlets (not shows), where outlets can be controlled individually. Invention has at least one of the following: touchscreen interface 119 or digital wireless communication interface 116. Those interfaces can be used to input time of use electrical rates and display information to the user on cost savings achieved. When wireless communication 116 is used, invention can either act as a web server, or communicate using data communication protocols. Invention can support both modes. A fan can be provided to cool down battery compartment (part of 131) and/or power conversion circuitry (not shown).

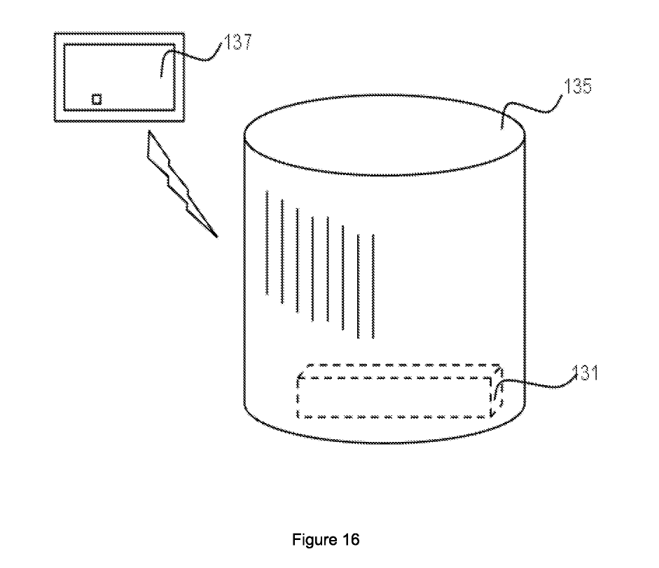

FIG. 16 shows how a household thermostat 137 can be used as user interface or controller for household utility appliances such as a whole house air conditioner 135.

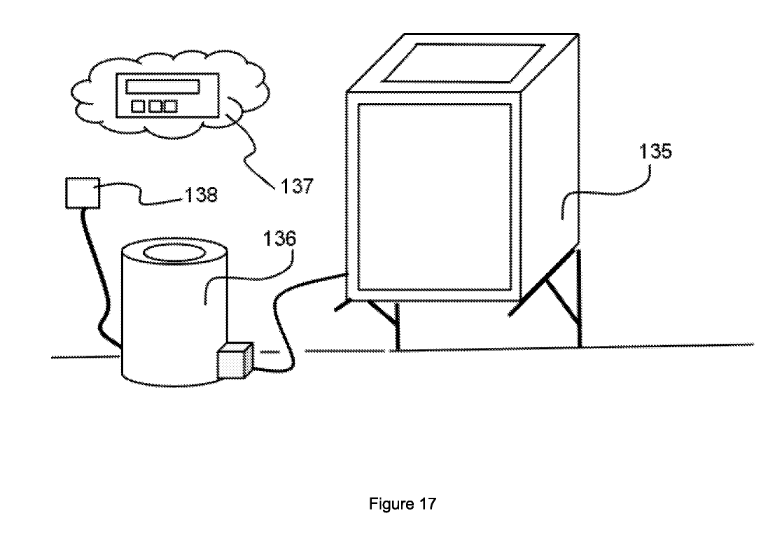

FIG. 17 shows how invention can be used to enable demand shifting of a legacy household appliances such as an air conditioner 135 having dedicated connection 138 to the AC power grid. The invention has an enclosure containing a Zebra battery and controller with necessary switching and charge/discharge circuitry (not shown). Household thermostat 137 is used for user interface and to communicate with household computing devices and the Internet.

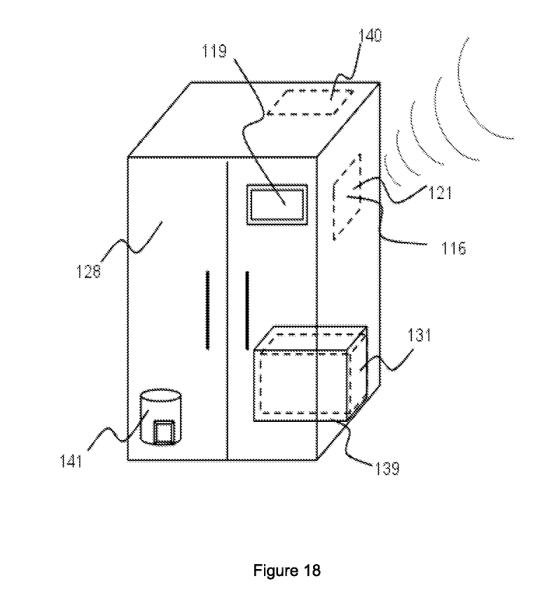

FIG. 18 shows the invention embodied as a refrigerator. The battery is placed in a special compartment 131. In some embodiments, this compartment is connected to the cooled compartment to provide for optimal battery operated temperature. In an embodiment, the compartment has a fan to provide for better temperature control. In some embodiments, the fan is operated by an electrical motor. In another embodiment, it can be operated by a Sterling machine.

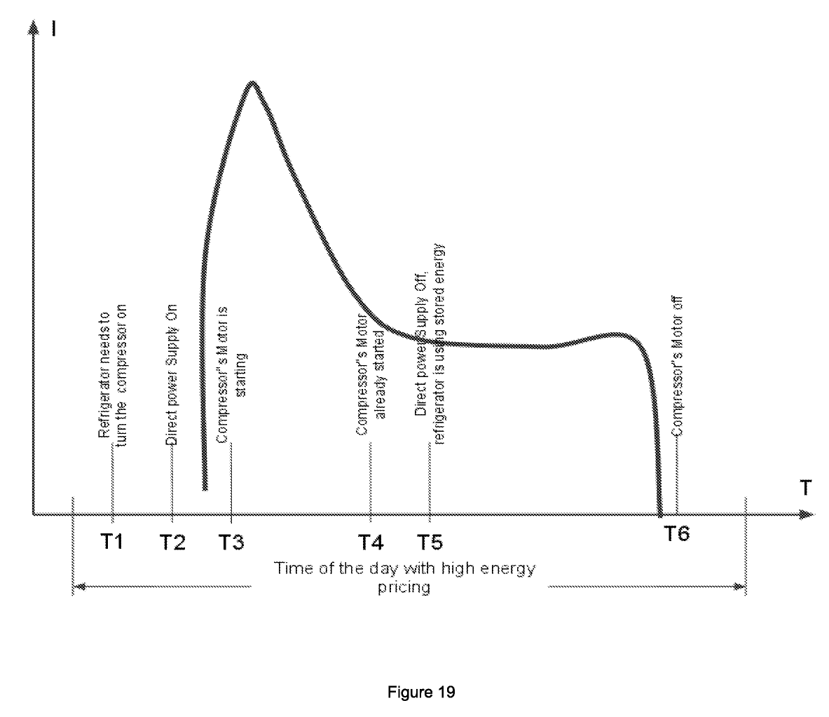

FIG. 19 illustrates current limiting method during battery operation period. In some embodiments, operating appliance of battery power at high currents can be detrimental to either battery state, or overall efficiency of the appliance. For example, startup current of electrical motor can be significant but short term. The damage to the battery due to the high current or the cost of the appliance (more powerful energy converter, capacitor, etc) out weights short term energy savings. In this regard, during high current load, the appliance switched from being battery powered to either using utility power, or combination of utility and battery power. In an embodiment, there is a threshold of maximum acceptable current. If a current sensor detects current above the threshold, direct connection 109 is activated, In an another embodiment, micro controller 103 controls the load 102, and enables direct connection 109 before engaging high current activities.

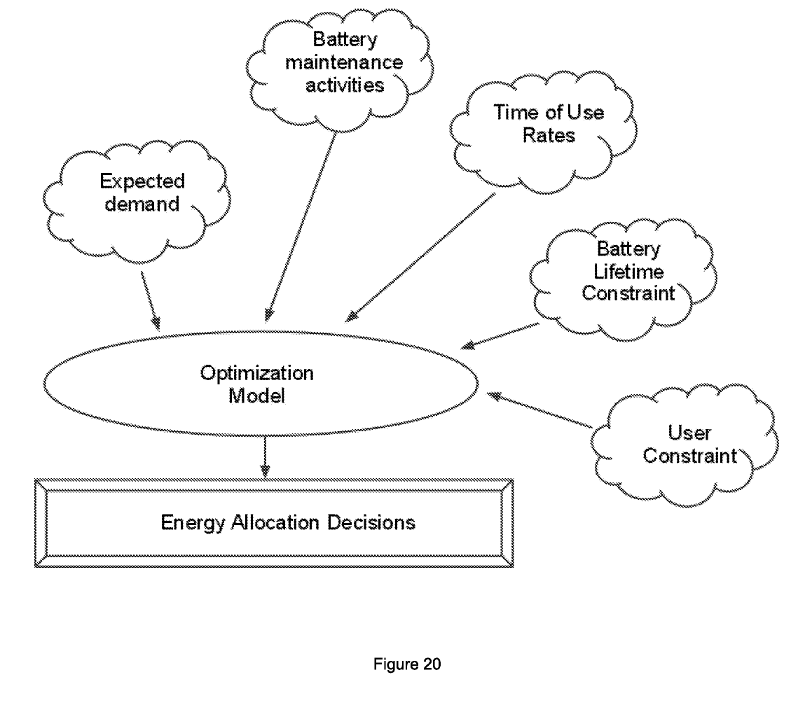

FIG. 20 illustrates the way energy allocation decisions can be made in an embodiment. At any given moment of time, battery can be either charging, or discharging, or idle. Battery storage costs can be defined as sum of energy losses due to the storage and charge/discharge; and battery deterioration costs. A list of potential energy allocations decisions to enhance battery life and capacity can be created. The techniques to improve battery life and capacity varies by battery chemistry and design and are explained, for example in the book “Batteries in a Portable World: A Handbook on Rechargeable Batteries for Non-Engineers” by I. Buchmann. A cost function that takes into account energy costs, storage costs, and potential battery lifetime improvements can be written down and optimized. In an embodiment, this is a liner, quadratic, convex, or non convex optimization function that is optimized by controller 106. In another embodiment, the energy allocation algorithm is decided during design given battery chemistry and typical demand pattern. In some embodiments, the outcome of optimization by controller 106 and design phase decision are essentially similar and involves the following
Discharging the battery during period of the maximum rates (cost saving)
Allocating discharge during the maximum rates either as closer as possible to the beginning of maximum rates, or as close as possible to the end of maximum rates (need, depending on the battery chemistry, either to minimize time battery is charged, or maximize such time).
   Charging battery at the period of low rates (cost saving)
Allocating the charge either closer to the beginning of low rate period, or to the end (need, depending on the battery chemistry, either to minimize time battery is charged, or maximize such time)
Periodically performing an activity to extend battery lifetime, such as deep/shallow charge/discharge, high or low current, use impulse charge etc).
For many battery chemistries, fully charging battery creates a negative effect. In an embodiment, battery is charged only to a level sufficient to satisfy forecasted energy demand. In an embodiment, a user interface is provided to override forecast and increase or decrease storage level. (less battery deterioration and power losses than prior-art full charge).

Direct optimization of the cost function

C=E+B+Δ

can be used using the invention micro-controller or a computing device coupled with the invention, As the cost function accounts for self-discharge costs and battery deterioration costs associated with been in a certain charge state, the invention will advantageously schedule the charge and discharge operation in a manner to reduce the totals costs of operating the invention. Further, the invention will select charge and discharge thresholds to minimize the totals costs.

For example, let us consider costs optimization strategy for a device with lead acid battery. Lead acid battery requires relatively infrequent maintenance, and less deteriorates if:
Kept in charged state as long as possible
Charged to a certain threshold
Discharged to a certain threshold
Charge and discharge currents are limited.

Therefore, optimizations of costs for a device with lead acid battery can be simplified into a series of decisions:
First of all, it is apparent that the entire period of lowest time of use rate is better to be used for charging with minimum current. If this current is too small for cost effective operation, the charging will just happen in the earliest subset of this interval.
A cost based decision can be made to extend the charge interval from the period of lowest time of use rates to the periods with higher, but still low rates. The decision is to balance reduced battery deterioration costs and improved battery v higher cost of energy. Change in the electricity rates values may cause change of scheduling.
Similarly, the most economical discharge mode is to use lowest possible current during the entire period of the highest time of use rates. If there is not enough battery capacity to run of battery the entire period of highest rates, the most economical mode will be to supplement battery with drawing current from AC grid. If it is not practical, an alternative approach will be to discharge the battery as late as possible during the peak high rate period.
A cost based decision can be made to extend the discharge interval from the period of highest time of use rates to the periods with lower, but still low rates. The decision is to balance reduced battery deterioration costs and improved battery capacity v higher cost of energy. Change in the electricity rates values may cause change of scheduling.
Charge and discharge thresholds can be selected to balance battery deterioration v energy costs. Change in the electricity rates values may cause change of a threshold.
Periodic maintenance charge and discharge with different currents and to different thresholds can be scheduled using logic independent from the main optimization algorithm.

As one skilled in the art can see, practical implementation of cost optimization algorithm can be done combined computationally cheap individual decisions pre-programmed taking into the account battery chemistry, and actual numerical optimization, that is manageable in this case even for a lower end MCU. An embodiment may use no numerical optimization beyond computing the individual balancing decisions.

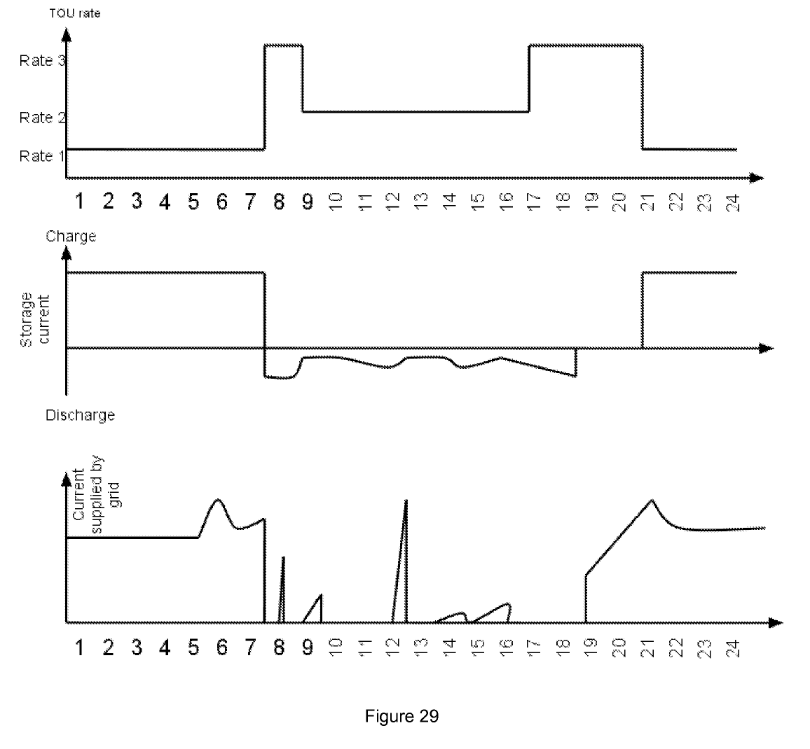

FIG. 29 illustrates a scenario when a battery discharge is allocated to the earlier part of the period with higher rates and additional AC current is supplied to the load supplementing battery supplied current

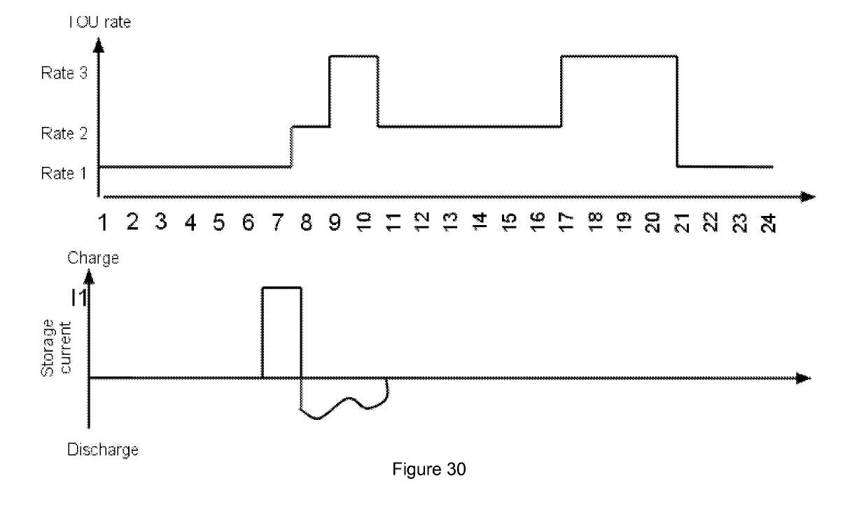

FIG. 30 illustrates allocation of battery discharge as close as possible to the period of time when maximum rates begin. Such scenario is suitable in cases where the storage battery chemistry is characterized by high rate of self discharge, but doesn't benefit from a highest charging rates. For example, the high-performance nickel-based batteries with enhanced electrode surface area and super conductive electrolyte might lose 5% of the charged capacity during the first hour after charging. The illustrated scenario shows TOU rates changing from their lowest value of one to higher rate at 7:30 a.m. and to the highest rate out of three at 9:00 a.m. In order to reduce the energy cost, the storage current switches from positive (charging) to discharging (negative) at 7:30 a.m. In order to reduce the storage cost elevated by self discharge, the battery discharges with a variable load during first 3 hours of highest TOU rates. In order to further reduce storage cost, the battery gets charged for a prolonged period of time by low current.

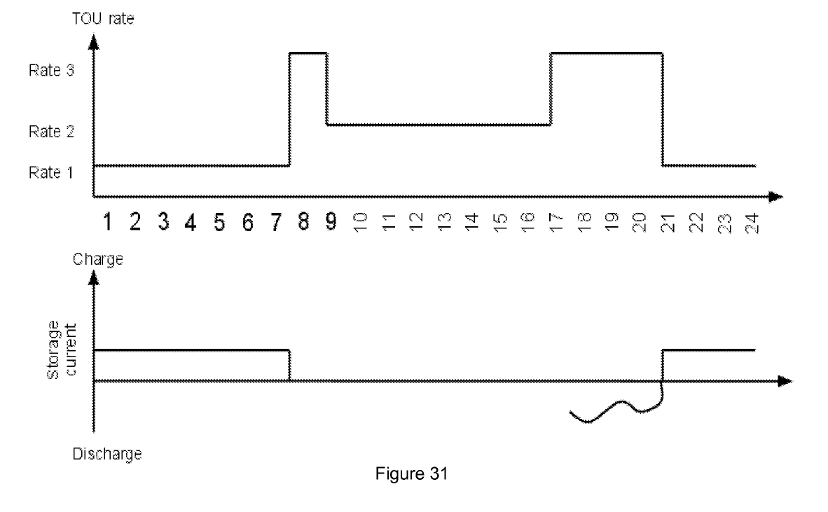

FIG. 31 illustrates allocation of battery discharge as close as possible to the end of the period with maximum rates. Such scenario is suitable in the case when the battery life time and overall capacity is negatively affected if it stays in a relatively deep discharged state. For example if an aged lead acid battery stays in 10% SOC for a duration of 4-5 hours, its capacity might be reduced. In order to optimize the storage costs, discharging of the battery gets started around 5 p.m. which keeps battery at SOC above 35% all the time until low TOU rate period of time starts and battery begins to charge.

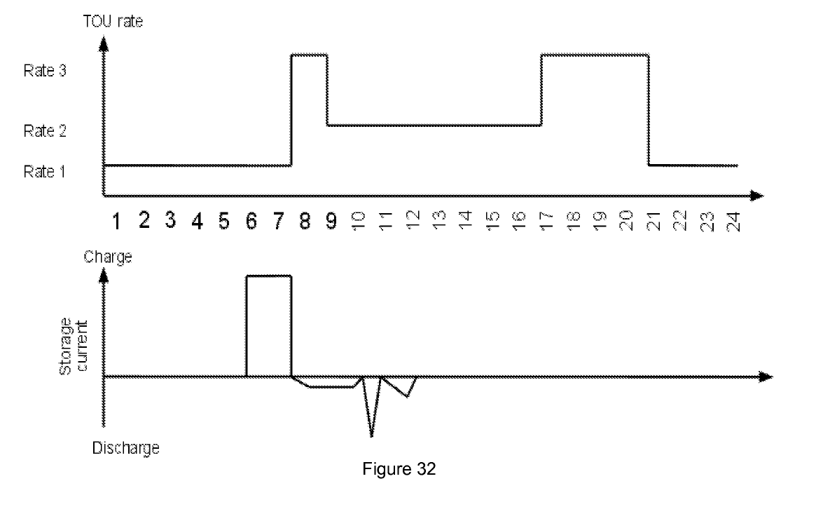

FIG. 32 illustrates the battery charging as close as possible to the end of the period with lowest rates and battery discharging starts immediately after higher TOU rates are in use. Such approach allows to reduce energy costs and storage costs in case if battery chemistry is such as is characterized by a higher self discharge and as is negatively effected by if it stays in a relatively deep discharged state. The battery chemistry in this case allows to use an elevated charging current. Storage cost reduction gets achieved by charging of battery by high current starting 1.5 hours before the end of the period with lowest TOU rates and discharging of the battery during first 4.5 hours of the higher TOU rates.

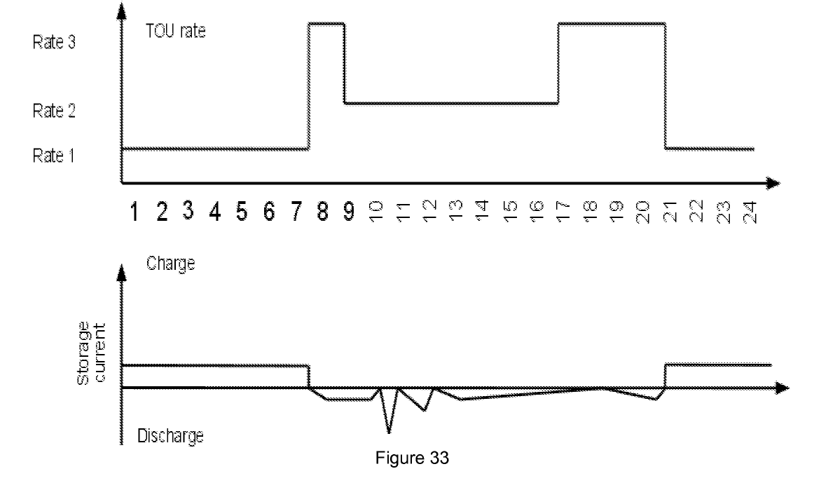

FIG. 33 illustrates the scenario when storage battery chemistry is characterized by low self discharge current and higher battery life and efficiency when it gets charged by low charging current. In order to reduce storage cost the battery starts charging as close as possible to the beginning of the period with lowest rates. Charging in this case is preferably done by a low charging current. For example the lead acid battery when it's charged by current lower then nominal charging current gets less effected by sulfatation and oxidation and overall battery life gets increased. In this case use of reduced charging current drops the storage costs. SOC. Battery charge efficiency is also a function of charge rate, with lower rates resulting in higher efficiencies. In this case the reduced storage cost gets achieved.

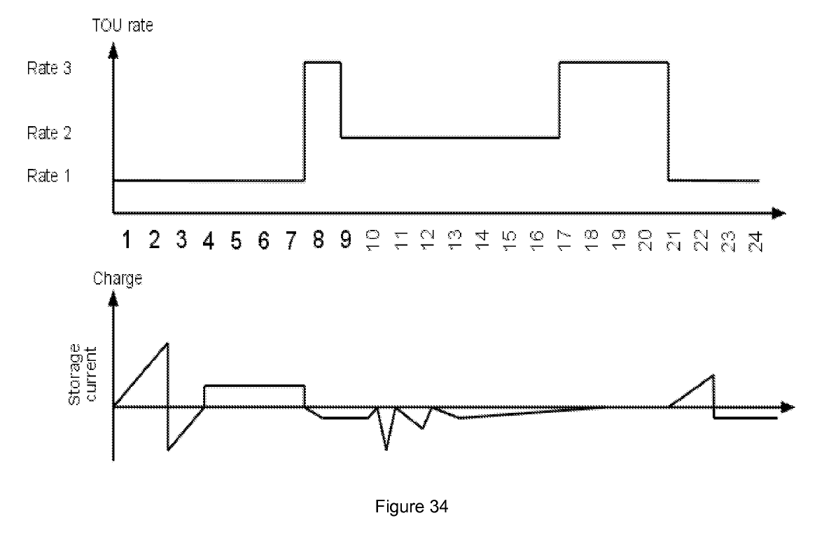

FIG. 34 illustrates periodic charge/discharge cycles to reduce the so called “voltage depression” effect on the battery. In this case the battery's cell output voltage might drop from 1.2 to about 1.05 volts partway through the discharge cycle. In order to reduce the storage cost the battery gets discharged until the total voltage drops to 1.0 volts per cell, and then it gets recharged recharge it. This will extend the battery life and improve the battery capacity. Charge/discharge cycling is best done during the period with lowest rates. Further improvement of storage costs is done due to keeping the battery capacity on a higher level by using low charging current. Because charge efficiency decreases with increasing battery state-of-charge, increasing of overall battery capacity positively effects the battery efficiency. For example when the lead acid battery gets charged from zero SOC to 84% SOC the average overall battery charging efficiency is 91%. keeping the battery capacity at higher level during it's life time will improve the storage cost.

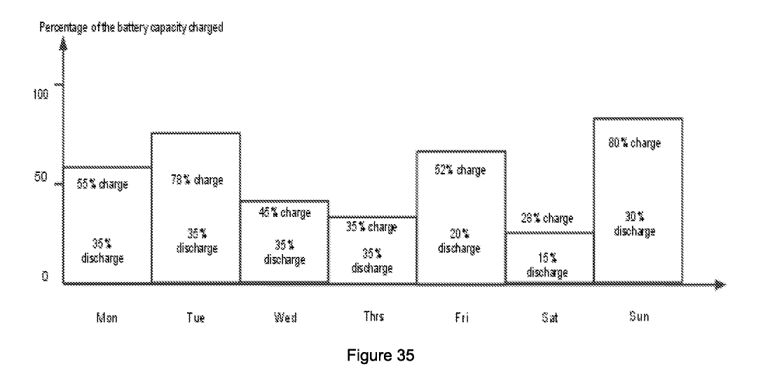

FIG. 35 illustrates a scenario when the lower storage cost will be achieved when the battery is charged only to a level sufficient to satisfy for-casted energy demand. This is suitable for the lead-acid storage battery. Seven days of the week it gets charged to SOC below 80%. It is charged to 80% capacity on Friday in anticipation of an event with the highest fore-casted energy consumption. The storage cost gets improved by charging of the battery always below 80%. It is well known in the art that when the lead-acid battery is never discharged below 10% SOC and charged above 80% SOC, it's charging efficiency is around 91%.

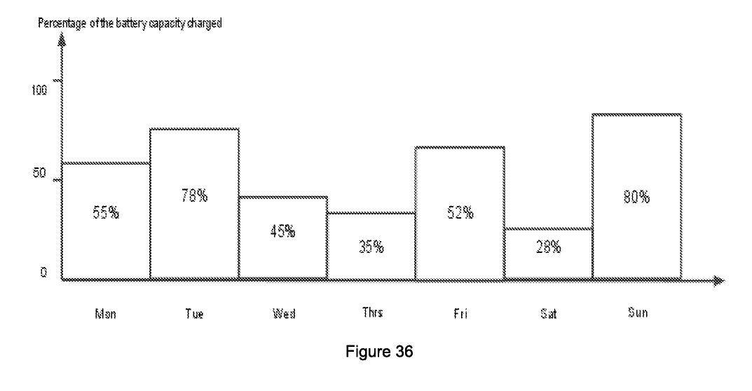

FIG. 36 illustrates a scenario when different charge and discharge limits are selected for each week day to minimize the totals storage costs. The storage cost reduction is achieved by keeping the battery SOC in the range between 10% and 80%. The energy cost reduction is achieved by charging the storage battery to each day fore-casted value, so the overall amount of energy is optimal.

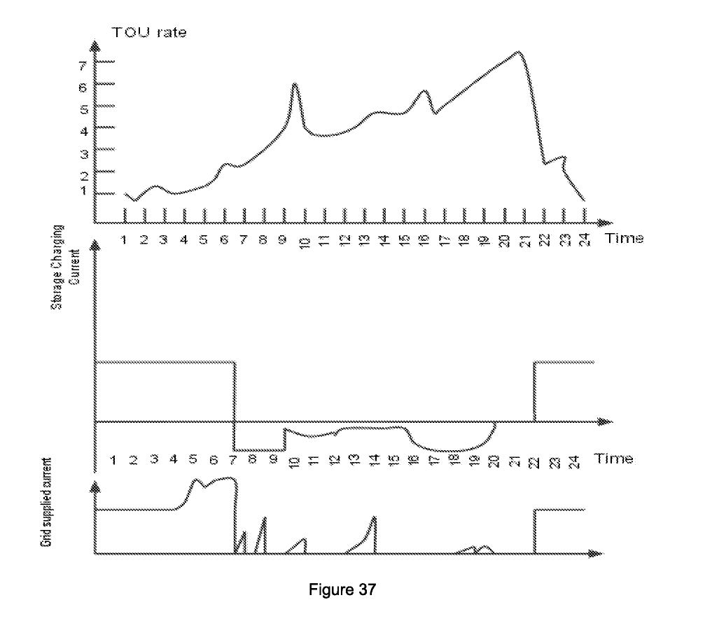

FIG. 37 illustrates a scenario when the required current is too high to be supplied by the battery without negatively affecting it's life time. In some cases the short period high current is required to be supplied to a home appliance For example a high starting current is drawn when the refrigerator compressor motor starts. The current reduces as the motor gathers speed In order to reduce storage cost an additional current from the grid is supplied even during times with highest TOU rates. The reduction of energy cost gets achieved by charging the storage battery during the lowest TOU rates.

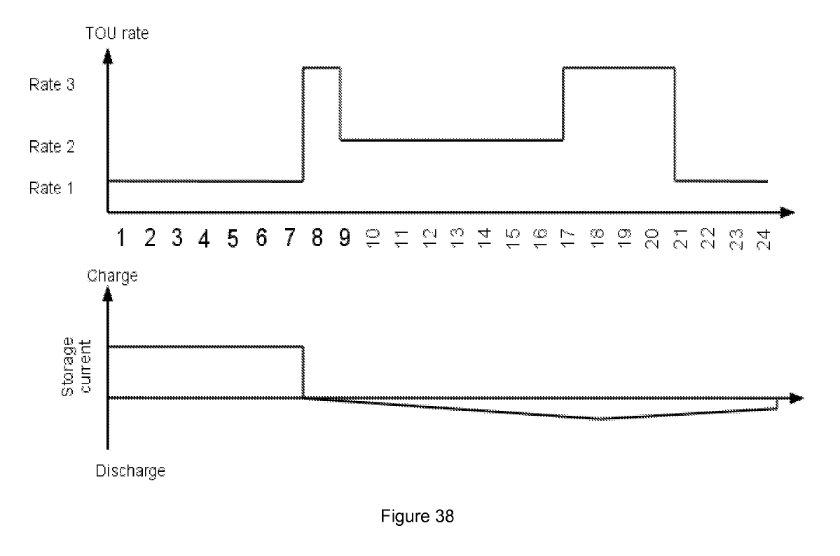

FIG. 38 illustrates a scenario when the decision is made to balance reduced battery deterioration costs and improved battery capacity against higher energy cost. In order to reduce storage cost the battery gets discharged to the lowest SOC even during a period of lowest rates. Such scenario is suitable for certain NiCd batteries which gradually lose their maximum energy capacity if they are repeatedly recharged after being only partially discharged. The battery appears to “remember” the smaller capacity. Such effect is some times called the “memory effect”. The energy cost reduction gets achieved by charging the battery during the lowest TOU rates.

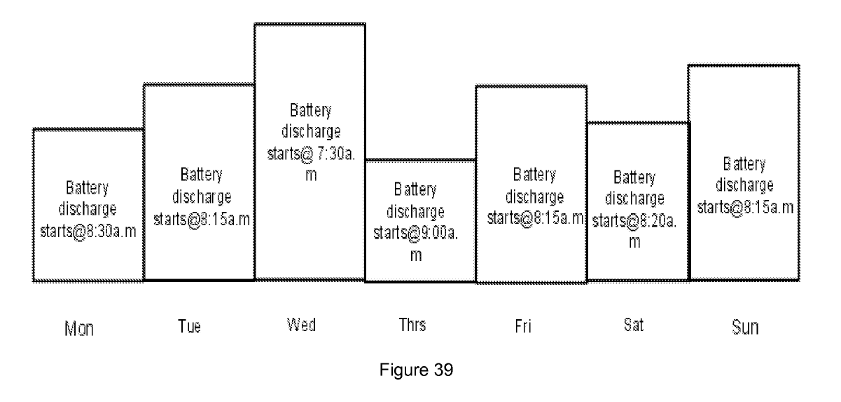

FIG. 39 illustrates a scenario when in order to reduce the energy cost the battery discharge allocation timing changes each week day according to the daily change in TOU rates schedule.

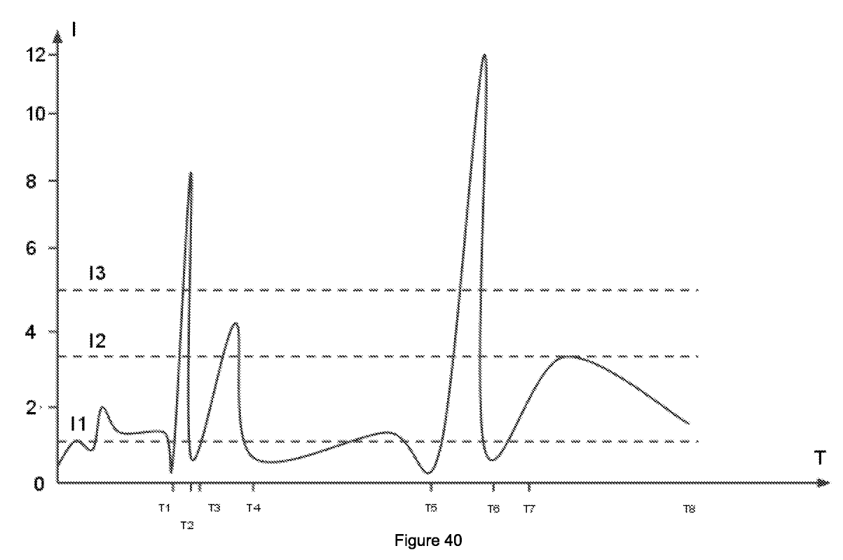

FIG. 40 illustrates a scenario when storage and energy costs are improved by using of 4-level power switching technique. The graph illustrates combined power consumption of appliance main compressor unit, secondary compressor and multiple sub-systems. Power to the appliance is provided by battery storage and utility power grid. In case of only sub-systems functioning, power P1 which is supplied by the storage battery varies between 0.15 A and 3.3 A. and power P2 which is supplied by utility grid is at zero level. During periods of time between T1 and T2, T3 and T4, T5 and T6, T7 and T8, main compressor unit and secondary compressor are getting started and getting stabilized. During these periods the storage battery is switching to higher supply mode and delivers power level P3 which exceeds 5 A. The remainder of power P4 gets supplied by utility grid and is reaching 5 A. Such advanced scheme of power delivery to the appliance provides improved storage cost due to the fact that the battery discharge current is limited to not more then 5 A and minimized energy cost due to the fact that only short term peak power gets supplied from utility grid even at highest TUO rate periods of the day. Let the power demand needed to operate the appliance when motor is already started be d₁ and the power demand needed to operate the appliance at a specific moment of motor start-up be d₂. During normal motor operation, d₁=l₁+l₂, where l₁>0 is the power level provided from the storage and l₂≧0 is the power level (can be zero) provided from the power grid. During startup d₁<<d₂=l₃+l₄, where l₃≧0 is the power level provided from the storage (now it can be zero) and l₄>0 is the power level (non-zero) provided from the power grid. Invention advantageously selects l₄>l₂, that limits l₃ and reduces battery deterioration caused by high current.

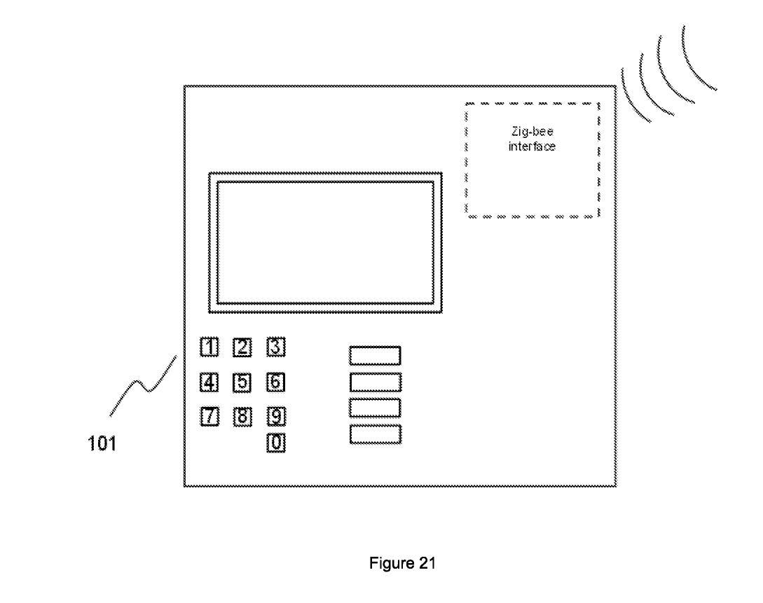

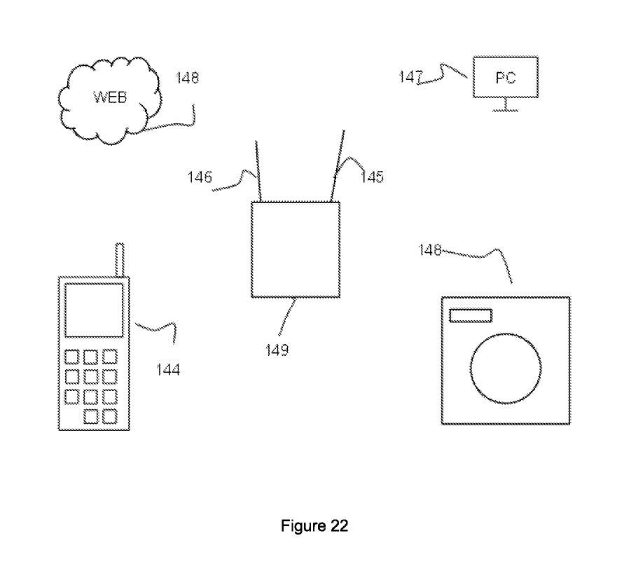

In an embodiment, TOU interface input and appliance management UI is implemented on household thermostat shown on FIG. 21. In another embodiment, these functions are implemented by a router style household gadget 149 shown on FIG. 22. The gadget 149 keeps the status and management interface available for Web 148 or Web Services access from PCs 147 and smartphones 144 and interacts with appliances 148 using ZigBee 146 or another digital wireless protocol 145. The gadget can either allow to enter time of use information from PCs or smartphones, or retrieve them from a server. The gadget may communicate energy use and savings information to an Internet server.

When there is a communication between appliances, home computing devices, and home energy management server, this communication can happens via various link layers, for example, Bluetooth, ZigBee, Ant, X10, etc. If the link layer is wireless, it preferably delivers secure and tamper free communication by usage of encryption and pairing techniques. Appliance may have a button that switches it into pairing or discovery mode.

On the data layer, the communication protocol is preferably standardized and includes the addresses the following communication needs:
a) Discovery—to exchange messages about appliance type, capabilities, available cycle and configuration options.
b) Energy allocation—to exchange messages about costs of specific energy allocation decisions and the actual decisions.
c) Status—historic energy consumption and costs, battery charge level and remaining lifetime, cycles executed.
d) Coordination—current and short term expected energy needs, duty cycle synchronization, time synchronization, etc.

XML or similar standard structured markup language is preferable used for data exchange. In some embodiments, the micro-controller is not powerful enough, so usage of fixed field width or another easy to parse format is desirable. Some embodiments can support both format. Stateless request/response data communication pattern is preferable. Some embodiments may use protocols where remote procedure calls or object access is implemented. For example, SOAP messaging can be used.

In embodiments, the following requests and fields for the datagrams can be used: getStatus, batteryChargeLevel, batteryLifeTime, energyUse, energyCosts, storageCosts, totalCosts, setEnergyRate, getEnergyRate, setAnticipatedUse, getAnticipatedUse, setCycleRequirements, getCycles, getMaintainceStatus, sendTextToDisplay, alert, optimizeCostFunction, getCostModel, etc.

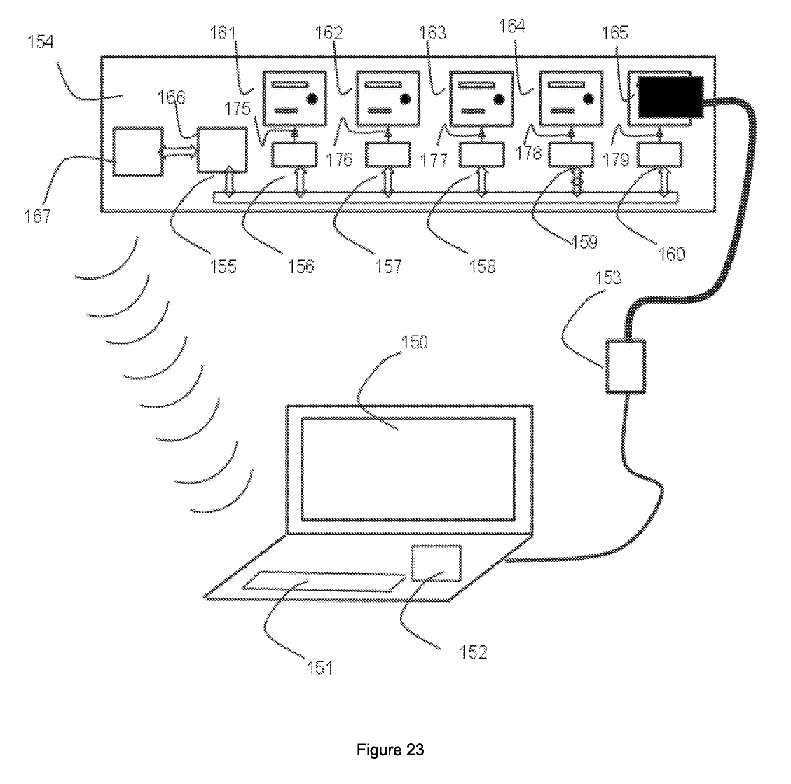

FIG. 23 shows a smart power bar adapted to practice the present invention and a laptop computer adapted to practice the present invention by software. The level of electrical energy supplied to each of the power outlets 160-165 is monitored by current sensing circuits 155-159. The power in each of the outlets can be cut off using the switchers @SW. The information from current sensing circuitry is advantageously used to compute the energy use and cost information. The switches advantageously used to enable demand shifting by temporary switching off the power supply to a legacy appliance. For example, power supply can be turned off for a limited time (15 or 30 mins) during the end of peak high energy rates for an appliance like refrigerator. This power bar can be used to enable demand shifting for a laptop computer 150. Most of off-the shelf laptop computers can not switch to using battery by software control. Thus, energy managing software 152 can be installed on the laptop to manage periods of time laptop will run off the battery. The actual switching to battery is managed by having the software communicate with the power bar.

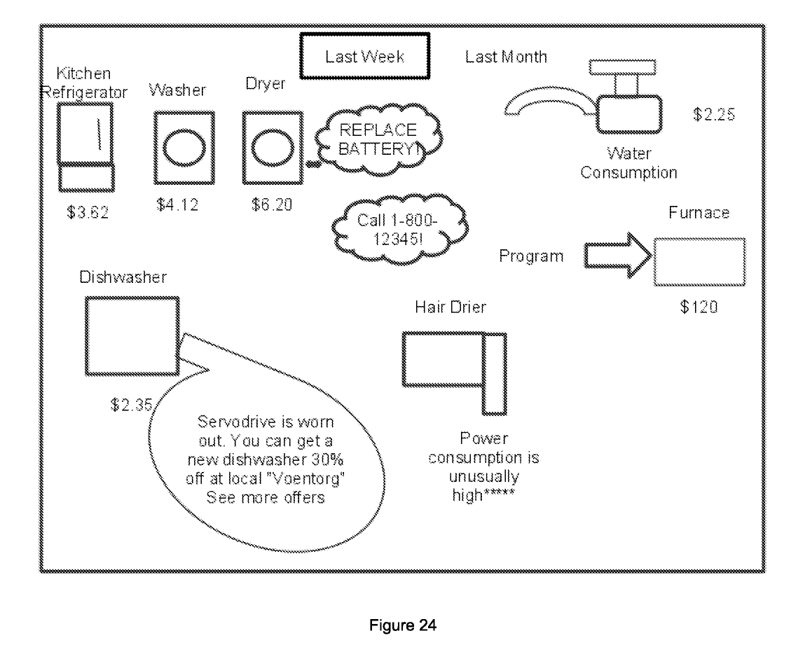

FIG. 24 shows an example of household energy management user interface designed according to the present invention. The interface provides information about historic energy usage and electricity costs for household utility appliances, and allows comparing those costs with the baseline. The interface advises user on maintenance and replacement needs for the appliances or their batteries. The interface further allows selection of future operations options, including demand shifting options, and advises user on anticipated energy costs. The interface can be embedded into a utility appliance, a household thermostat, provided by a web interface, or by a special application on household computing device.

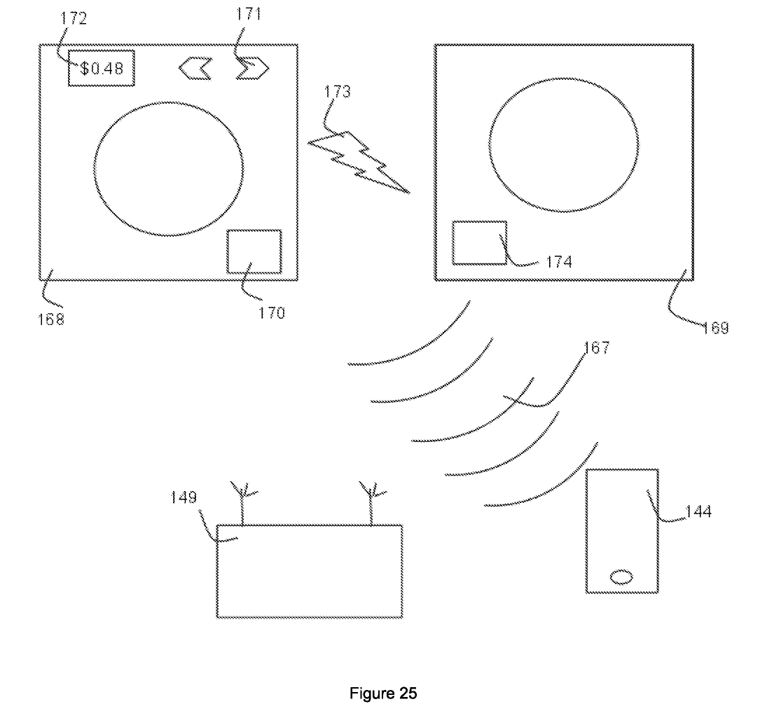

FIG. 25 shows a washer/dryer pair designed according to the present invention and interacting with a household energy management user interface according to the present invention. Washer 168 provides user interface and cycle selection options for both washer and dryer 169. By pressing buttons user change cycle options, including demand shifting options. Washer displays anticipated energy costs. User selects cycle that balances user needs and costs. Data are transferred between washer and dryer using communication link 173. A smartphone 144 can be used as an alternative user interface. Washer receives TOU rates from a household energy management server 149 over wireless communication link 167.

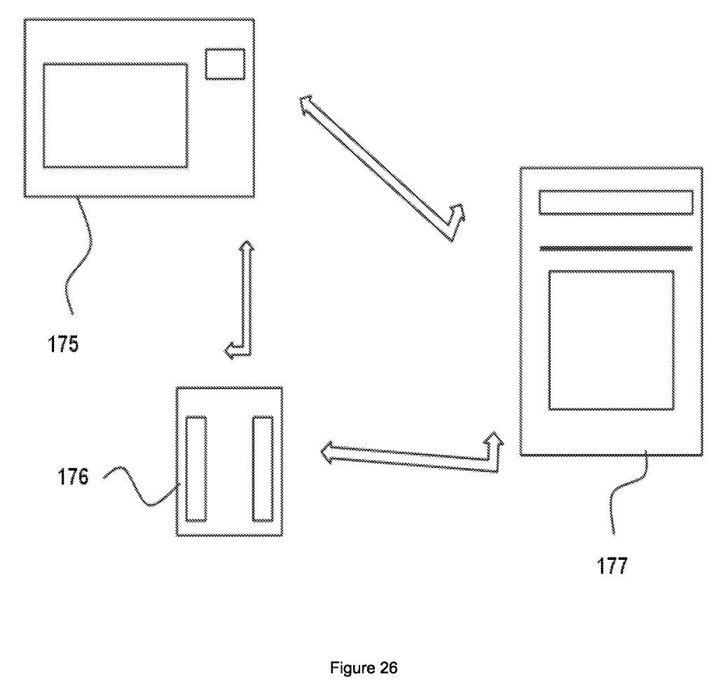

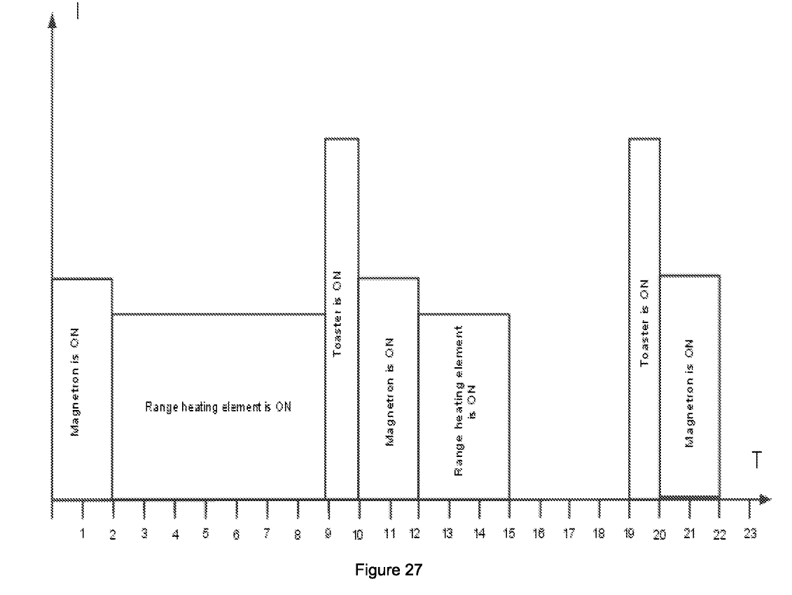

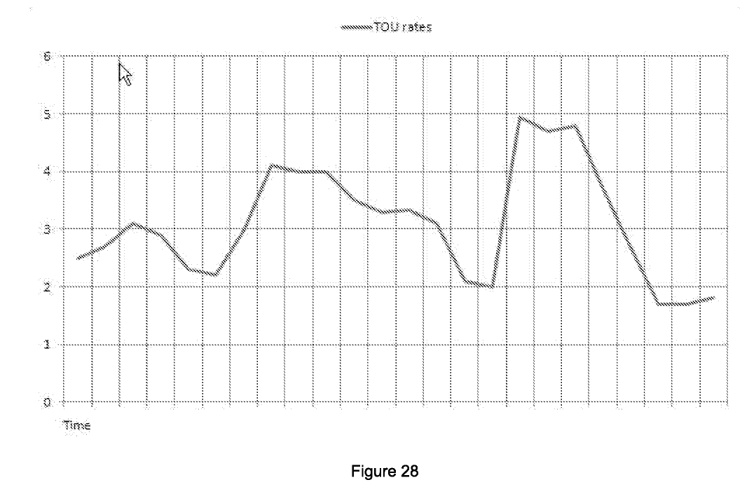

FIGS. 26, 27 illustrates stove, microwave, and toaster coordinating their duty cycles to reduce peak current drawn from the household AC grid. Those appliances, while ON, consume energy according to a duty cycle (e.g., for 5 seconds each 15 seconds). If those duty cycles are not synchronized, peak consumption is too high, creating undue demands on wiring, renewable energy source, and whole house demand shifting storage. In an embodiment, numerous appliances designed according to the principles of this invention, coordinate their duty cycle to reduce the peak demand and achieve more uniform load. Such coordination may happen by passing duty cycle token over wireless communication or by control from home energy management server, or by time synchronization and pre-allocation of duty cycle.

### DEFINITIONS AND CLARIFICATIONS OF CERTAIN TERMS AND CONCEPTS

Demand shifting is changing electrical consumption timing to achieve peak demand reduction and/or electrical cost reduction. As a result of demand shifting, overall energy consumption is not normally reduced, and can be even increased due to use of an electrical energy storage and associated losses.

Utility appliance is a household appliance having direct and visible utility to a consumer, such as washer, dryer, refrigerator, stove, extension cord, power bar, etc.

Practical use scenario is a scenario that allows appliance to fulfill a utility function. For example, use scenario where dishwashing is delayed till mid-night is practical, but the scenario where power is not supplied to refrigerator for a prolonged period of time is not practical (food will spoil).

Demand or power consumption level by an appliance or an enclosure includes energy needed to operate utility function, including energy for one or more other appliances supplied through the appliance or enclosure; but excludes energy used to charge the storage in anticipation of further demands.

Charge or discharge operation is not necessary continues and may includes time of zero current or small discharges/or charges performed for storage optimization purposes.

Available battery capacity is capacity available to a normal charge/discharge cycle, but does not includes capacity that can be recovered during periodic maintance charge/discharge.

Maintenance charge/discharge cycle is cycle that is less energy efficient that routine charge/discharge cycle, but reduces battery deterioration. The energy obtained during discharge operation preferably used for the appliance operation, but it can also be not used at all.

1. An appliance,
the appliance providing a household utility function different from power metering,
the appliance comprising of:
a power connection which receives power from a household power grid,
a set of at least one micro-controllers;
the appliance operable to:
a) receive a plurality of time of use electrical pricing rates, each rate associated with at least one time interval,
b) for a plurality of appliance use scenarios, compute one of the following:
i. the costs of operating the said appliance for at least two different use scenarios,
ii. the cost difference in costs of operating the said appliance between two different use scenarios,
iii. at least one value indicative of the absolute or relative costs of two different use scenarios;
wherein:
said costs comprise the cost of electricity received by said power connection to perform said use scenarios based on said time of use rates,
in the said plurality of appliance use scenarios there are at least two use scenarios that are practical, and one of the scenarios in the said two is the demand shifting of the other,
operations (a) and (b) above are performed using one of the following options:
using the said set of micro-controllers,
using another computing device that communicates with the said appliance.

2. The appliance as recited by claim 1, wherein the said utility function is one of the following:
a) a refrigerator,
b) a dishwasher,
c) a washer,
d) a dryer,
e) a cooking appliance,
f) a heater,
g) an air conditioner,
h) an entertainment unit.

3. The appliance as recited by claim 1, wherein the said utility function is an extension cord or power bar, and the said appliance further comprises a power plug and at least one power outlet.

4. The appliance as recited by claim 1, wherein the said plurality of the use scenarios comprises at least two scenarios starting at substantially the same time and achieving substantially the same utility function.

5. The appliance as recited by claim 3, further operable to switch on or off power supply in the said power outlet.

6. The appliance as recited by claim 1 further comprises of electrical energy storage and
a) further operable to perform a charge/discharge cycle of said storage,
b) said charge/discharge cycle comprising of at least one charge operation and least one discharge operation,
wherein
c) said discharge operation provides at least a portion of the energy to operate the said appliance,
d) at least a portion of the charge operation is performed during a first time interval,
e) at least a portion of the discharge operation is performed during a second time interval,
f) the time of use electricity pricing rate associated said first time interval is lower than the rate associated said second time interval.

7. The appliance as recited by claim 6, wherein the said costs further comprises the costs associated with deterioration of the said storage.

8. The appliance as recited by claim 6 wherein during the said discharge operation
a) there is a first non-zero energy consumption level by the said appliance,
b) there is a second non-zero energy consumption level by the said appliance,
c) the said second energy consumption level is greater than the said first energy consumption level,
d) the said first energy consumption level is fulfilled by a first non-zero power level from the discharge of the said storage and a second power level provided from the said power connection to household power grid,
e) the said second energy consumption level is fulfilled by a third power level from the discharge of the said storage and a fourth non-zero power level provided from the power connection to household power grid,
f) the said forth power level is greater than the said second power level.

9. The appliance as recited by claim 1 wherein at least one of the said use scenarios is a past use of the appliance.

10. The appliance as recited by claim 9, wherein the said plurality of use scenarios includes at least 2 past uses during different time intervals.

11. The appliance as recited by claim 1 wherein at least one of the said use scenarios is anticipated in the future.

12. The appliance as recited by claim 1 wherein at least a portion of the results of computation in step (c) is provided to a user using one of the following options:
a) A user interface device that is part of the appliance,
b) A user interface device that is communicates with the appliance.

13. The appliance as recited by claim 4 wherein
a) at least a portion of the results of computation in step (c) is provided to a user using one of the following options:
i. A user interface device that is part of the appliance,
ii. A user interface device that is communicates with the appliance;
b) at least one of the said use scenarios is anticipated in the future,
c) following the step a), the appliance is further operable to receive a user input indicative to a selection a use scenario to be performed in the future.

14. The appliance as recited by claim 11, wherein a computing device selects one of the said anticipated use scenarios.

15. The appliance as recited by claim 6, wherein the said plurality of use scenarios includes at least two scenarios involving charging or discharging of the said storage.

16. A method of demand shifting for a household utility appliance, the method comprising the steps of:
a) receiving a plurality of anticipated time of use electrical rates, each rate associated with at least one time interval,
b) for plurality of practical anticipated appliance use scenarios, perform at least one of the following computations:
i. costs of operating the said appliance in at least two of the said use scenarios,
ii. difference in costs of operating the said appliance between two of the said use scenarios,
iii. at least one value indicative of absolute or relative costs of the said use
scenarios,
c) selecting one of the said use scenarios,
wherein
the computation step b) is performed using one of the following:
by a computing device that is a part of the appliance,
by a computing device that communicates with the appliance,
the said costs comprise of the costs of electrical energy received from utility grid for the said appliance according to the said rate schedule.

17. Method as recited in claim 16, wherein the said selection step is done by a computing device.

18. Method as recited in claim 16, wherein results of the said computation are provided to a user and the said selection step is in response to an input from the user.

19. An appliance with a household utility function different from:
power metering,
power supply,
connection of another utility appliance to household power grid,
the appliance comprising a set of at least one micro-controllers, the said set is operable to
a) receive a plurality of time of use electrical rates, each rate associated with at least one time interval,
b) monitor the amount of electricity the appliance uses,
c) compute the costs to operate the appliance over a period of time in the past, wherein:
the said period intersects with a plurality of the time intervals,
at least two of the time intervals from the said plurality have different associated time of use electricity rates,
the said costs comprise the cost of electricity consumed over the said period, the cost of electricity is computed using the said time of use rates,
d) communicate the said costs to a user.

20. The appliance as recited by claim 19, wherein the said appliance comprises a user interface device, the said device is used for at least one of the steps a) or d).
